(19) United States
(12) Patent Application Publication
(10) Pub. No.: US 2012/0061703 A1
(43) Pub. Date: Mar. 15, 2012

(54) LIGHT EMITTING DEVICE AND MANUFACTURING METHOD OF LIGHT EMITTING DEVICE

(75) Inventor: Mitsuhiro KOBAYASHI, Kanagawa-Ken (JP)

(73) Assignee: Kabushiki Kaisha Toshiba, Tokyo (JP)

(21) Appl. No.: 13/151,216

(22) Filed: Jun. 1, 2011

(30) Foreign Application Priority Data
Jun. 1, 2010 (JP) 2010-125746

(51) Int. Cl. H01L 33/44; H01L 33/52

(52) U.S. Cl. 257/98; 438/26; 257/E33.06; 257/E33.059

(57) ABSTRACT

A light emitting device may include a base provided with a recess portion in a side surface thereof, a light emitting element mounted on a main surface of the base, a first resin body filled in an inside of the recess portion, and covering at least the main surface and the light emitting element, a second resin body covering an outside of the first resin body from the main surface side to at least a position of the lowermost end of the recess portion in a direction orthogonal to the main surface, and phosphor, provided in the second resin body, for absorbing light emitted from the light emitting element and then emitting light having a different wavelength.

### CROSS REFERENCE TO RELATED APPLICATION

This application is based upon and claims the benefit of priority from Japanese Patent Application No. 2010-125746, filed on Jun. 1, 2010, the entire contents of which are incorporated herein by reference.

### BACKGROUND

For a light emitting device such as a light emitting diode (LED), adopted is a structure in which: a LED chip mounted on a lead is housed in a recess structure of a resin package; and the LED chip is sealed with a phosphor-containing resin in a covering manner. Moreover, from the view point of reducing the size of the package, adopted is a structure in which: a LED chip is mounted on a lead; and the periphery of the LED chip is sealed with a phosphor-containing resin in the covering manner. Furthermore, for the resin package having the recess structure as described above, adopted is a structure in which: a LED chip in the recess structure is sealed with a transparent resin; and the recess structure is capped with a phosphor-containing cap.

However, in the structures in which the LED chip is sealed with the phosphor-containing resin, the distance that light travels through the phosphor-containing resin differs between a right upward direction and an oblique direction in an optical path along which light emitted from the LED chip travels through the package and is emitted to the outside. This difference causes difference in chromaticity among center portions and circumferential portions of the package. Although such difference is less likely to occur in the structure in which the recess structure is capped with the phosphor-containing cap, this structure requires additional steps of forming the cap, and of capping the recess structure with the cap.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a perspective view illustrating a light emitting device according to this embodiment.

FIG. 2A is a cross-sectional view illustrating the light emitting device according to this embodiment.

FIG. 2B is a plan view illustrating a lead frame.

FIGS. 3A and 3B are schematic cross-sectional views illustrating the light emitting device according to this embodiment. FIG. 3A is a cross-sectional view of the light emitting device taken along the A-A line shown in FIG. 1. FIG. 3B is a cross-sectional view of the light emitting device taken along the B-B line shown in FIG. 1.

FIG. 4 is a flowchart illustrating the method of manufacturing the light emitting device according to this embodiment.

FIGS. 5A to 10B are cross-sectional views illustrating steps in the method of manufacturing the light emitting device according to this embodiment.

FIG. 11A is a plan view illustrating the lead frame in this embodiment. FIG. 11B is a partially enlarged plan view illustrating element regions in the lead frame.

FIGS. 12A to 12H are cross-sectional views illustrating steps in the method of forming the lead frame according to this modification.

FIGS. 13A to 15B are cross-sectional views illustrating steps in a method of manufacturing a light emitting device according to this modification.

FIG. 16 is a cross-sectional view illustrating a light emitting device according to a second embodiment.

FIGS. 17A to 18C are cross-sectional views illustrating steps in the method of manufacturing the light emitting device according to this embodiment.

FIG. 19 is a schematic cross-sectional view illustrating a light emitting device according to a third embodiment.

FIG. 20 is a schematic cross-sectional view illustrating a modification of the third embodiment.

FIG. 21 is a schematic cross-sectional view illustrating a light emitting device of a fourth embodiment.

FIG. 22 is a perspective view illustrating a light emitting device according to a fifth embodiment.

FIG. 23 is a cross-sectional view illustrating the light emitting device according to the fifth embodiment.

FIG. 24 is a perspective view illustrating a light emitting device of a 6th embodiment.

FIG. 25 is a cross-sectional view illustrating the light emitting device of the 6th embodiment.

FIG. 26 is a perspective view illustrating a light emitting device of a seventh embodiment.

FIG. 27 is a cross-sectional view illustrating the light emitting device of the seventh embodiment.

FIG. 28 is a perspective view illustrating a light emitting device of an eighth embodiment.

FIG. 29 is a cross-sectional view illustrating the light emitting device of the eighth embodiment.

FIG. 30 is a perspective view illustrating a light emitting device of a 9th embodiment.

FIG. 31 is a cross-sectional view illustrating the light emitting device of the 9th embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

Embodiments of the present invention will be described based on the drawings.

Note that the drawings are schematic or conceptual. Relationships between the thicknesses and the widths of parts, ratios between the sizes of parts, and the like may differ from actual ones. Moreover, the same part may be illustrated in different dimension and ratio from one drawing to another.

Furthermore, similar components which have been already described in the previous drawings will be denoted with the same reference numerals, and detailed description thereof will be omitted as appropriate.

In addition, an XYZ-orthogonal coordinate system is used in this specification for convenience of description. Among directions parallel to upper surfaces of a first lead portion 11 and a second lead portion 12, a direction heading from the first lead portion 11 to the second lead portion 12 is referred to as a +X direction. Among directions perpendicular to the upper surfaces of the first lead portion 11 and the second lead portion 12, a direction heading upward, that is to say, a direction in which a later-described light emitting element 14 is mounted in a view from the first and second lead portions is referred to as a +Z direction. Among directions orthogonal to both the +X direction and the +Z direction, one direction is referred to as a +Y direction. Note that directions opposite to the +X direction, the +Y direction, and the +Z direction are referred to as a −X direction, a −Y direction, and a −Z direction, respectively. Moreover, for example, the “+X direction” and the “−X direction” may be collectively referred to as the “X direction.”

### First Embodiment

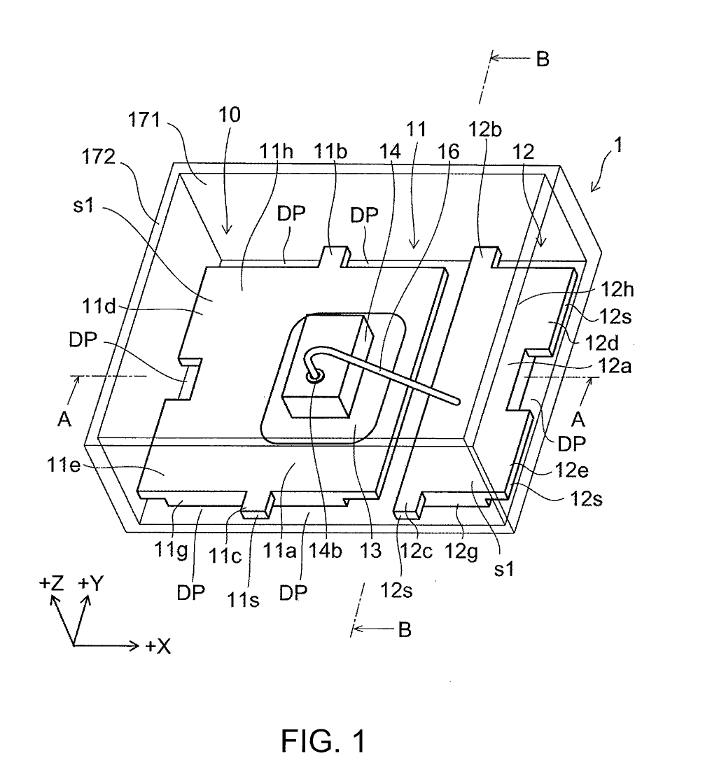

FIG. 1 is a perspective view illustrating a light emitting device according to this embodiment.

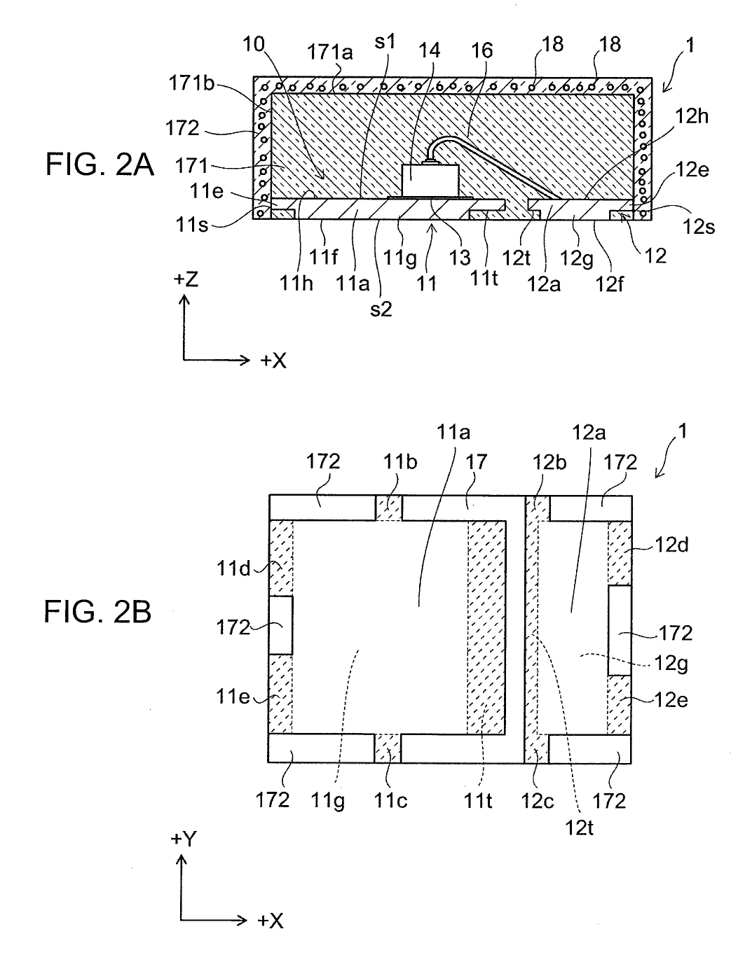

FIG. 2A is a cross-sectional view illustrating the light emitting device according to this embodiment. FIG. 2B is a plan view illustrating a lead frame.

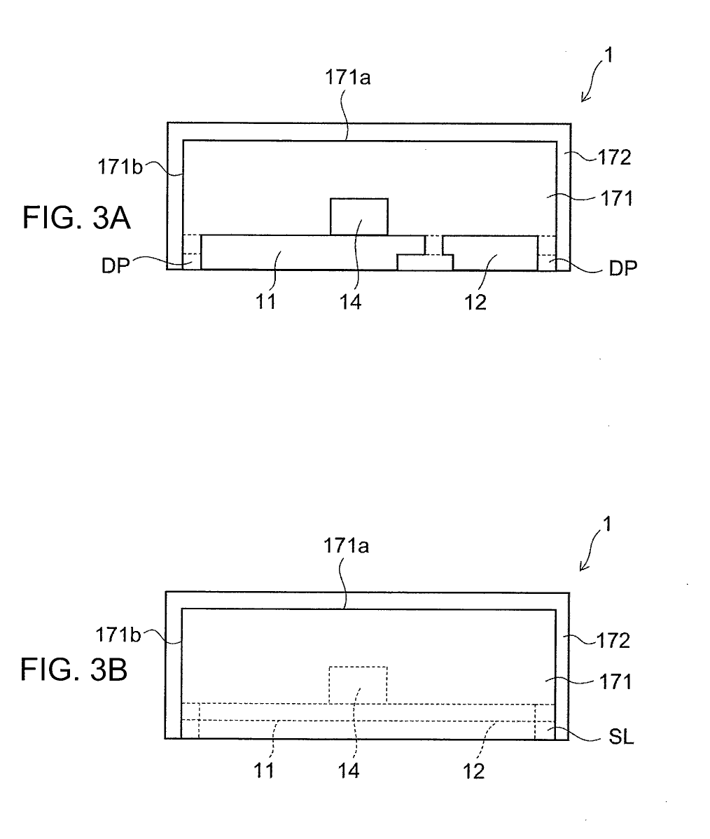

FIGS. 3A and 3B are schematic cross-sectional views illustrating the light emitting device according to this embodiment. FIG. 3A is a cross-sectional view of the light emitting device taken along the A-A line shown in FIG. 1. FIG. 3B is a cross-sectional view of the light emitting device taken along the B-B line shown in FIG. 1.

In order to make the drawings easy to see, phosphor particles are illustrated in larger size and smaller number than an actual case. Moreover, the phosphor is omitted in the drawings other than FIG. 2. Since FIGS. 3A and 3B is a schematic view mainly illustrating an arrangement of main components, only a lead, a light emitting element, and resin bodies are illustrated, and a die-mount material, a wire, and the phosphor are omitted in FIGS. 3A and 38. Furthermore, hatching indicating cross sections is omitted in FIGS. 3A and 3B. Such a way of illustration applies to other schematic cross-sectional views to be described later.

As shown in FIG. 1, the light emitting device 1 according to this embodiment includes: a lead (base) 10 provided with recess portions DP on side surfaces thereof; a light emitting element 14 mounted on a base portion 11a on a first main surface s1 of the lead 10; a first resin body 171 provided on the first main surface s1 side of the lead 10; and a second resin body 172 covering the exterior of the first resin body 171; and phosphor 18 which is contained in the second resin body 172, and which absorbs light emitted from the light emitting element 14 and emits light with a wavelength different from that of the absorbed light.

The lead 10 includes a first lead portion (first base portion) 11 and a second lead portion (second base portion) 12. The first lead portion 11 and the second lead portion 12 each have a flat plate shape, and are disposed on the same plane with a space therebetween. The first lead portion 11 and the second lead portion 12 are made of the same electrically conductive material. For example, the first lead portion 11 and the second lead portion 12 are each a copper plate with silver plating layers formed respectively on upper and lower surfaces thereof. Note that no silver plating layer is formed on edge surfaces of the first lead portion 11 or the second lead portion 12, and the copper plates are exposed therefrom.

The first lead portion 11 is provided with one base portion 11a which has a rectangular shape when viewed in the Z direction. Four hanging pins 11b, 11c, 11d, 11e extend out from the base portion 11a. The hanging pin 11b extends out in the +Y direction from a portion at the center, in the X direction, of an edge of the base portion 11a facing in the +Y direction. The hanging pin 11c extends out in the −Y direction from a portion at the center, in the X direction, of an edge of the base portion 11a facing in the −Y direction. As described, the hanging pins 11b to 11e extend out from three different sides of the base portion 11a. The positions of the hanging pins 11b, 11c in the X direction are the same. The hanging pins 11d, lie extend out in the −X direction respectively from both end portions of an edge of the base portion 11a facing in the −X direction. Since the hanging pins 11b to 11e are provided at intervals on the side surfaces 11s of the first lead portion 11, the recess portion DP is formed between each adjacent two of the hanging pins 11b to 11e.

The second lead portion 12 is shorter than the first lead portion 11 in the length in the X direction, while the second lead portion 12 is equal to the first lead portion 11 in the length in the Y direction. The second lead portion 12 is provided with one base portion 12a which has a rectangular shape when viewed in the Z direction. Four hanging pins 12b, 12c, 12d, 12e extend out from the base portion 12a. The hanging pin 12b extends out in the +Y direction from an end portion, on the −X direction side, of an edge of the base portion 12a facing in the +Y direction. The hanging pin 12c extends out in the −Y direction from an end portion, on the −X direction side, of an edge of the base portion 12a facing in the −Y direction. The hanging pins 12d, 12e extend out in the +X direction respectively from both end portions of an edge of the base portion 12a facing in the +X direction. As described, the hanging pins 12b to 12e extend out from three different sides of the base portion 12a. The width of each of the hanging pins 11d, 11e of the first lead portion 11 may be equal to the width of each of the hanging pins 12d, 12e of the second lead portion 12, or may be different. Note that, if the width of each of the hanging pins 11d, 11e of the first lead portion 11 is made different from the width of each of the hanging pins 12d, 12e of the second lead portion 12, an anode and a cathode can be distinguished from each other easily. Since the hanging pins 12b to 12e are provided at intervals on the side surfaces 11s of the second lead portion 12, the recess portion DP is formed between each adjacent two of the hanging pins 12b to 12e.

A protruding portion 11g is formed on a lower surface 11f of the first lead portion 11, and is located in a center portion of the base portion 11a in the X direction. Accordingly, the first lead portion 11 has two values in thickness. Specifically, the center portion of the base portion 11a in the X direction, that is to say, the portion where the protruding portion 11g is formed, is relatively large in thickness, while both end portions of the base portion 11a in the X direction and the hanging pins 11b to 11e are relatively small in thickness. In FIG. 2B, a portion in the base portion 11a where no protruding portion 11g is formed is shown as a thin plate portion 11t. Similarly, a protruding portion 12g is formed on a lower surface 12f of the second lead portion 12, and is located in a center portion of the base portion 12a in the X direction. Accordingly, the second lead portion 12 has two values in thickness as well. Specifically, the center portion of the base portion 12a in the X direction is relatively large in thickness since the protruding portion 12g is formed there, while two end portions of the base portion 12a in the X direction and the hanging pins 12b to 12e are relatively small in thickness. In FIG. 2B, a portion in the base portion 12a where no protrusion 12g is formed is shown as a thin plate portion 12t. In other words, on the lower surfaces of the two end portions, in the X direction, of each of the base portions 11a, 12a, cutouts extending in the Y direction are formed along the edges of the base portions 11a, 12a. Note that in FIG. 2B, the relatively-thin portions of the first lead portion 11 and the second lead portion 12, that is to say, the thin plate portions and the hanging pins are shown hatched by broken lines.

The protruding portions 11g, 12g are formed in regions located away from the opposed edges of the first lead portion 11 and the second lead portion 12, respectively. Regions including these edges are the thin plate portions 11t, 12t. An upper surface 11h of the first lead portion 11 and an upper surface 12h of the second lead portion 12 are on the same plane. A lower surface of the protruding portion 11g of the first lead portion 11 and a lower surface of the protruding portion 12g of the second lead portion 12 are on the same plane. The upper surface 11h of the first lead portion 11 and the upper surface 12h of the second lead portion 12 are the first main surface s1. The positions of upper surfaces of the hanging pins in the Z direction coincide with the positions of the upper surfaces of the first lead portion 11 and the second lead portion 12. Thus, the hanging pins are disposed on the same XY plane.

On the upper surface 11h of the first lead portion 11, a die-mount material 13 is applied to a portion of a region corresponding to the base portion 11a. In this embodiment, the die-mount material 13 is electrically conductive. The die-mount material 13 is made of, for example, silver paste, solder, eutectic solder, or the like.

The light emitting element 14 is provided on the die-mount material 13. Specifically, the light emitting element 14 is fixed to the first lead portion 11 with the die-mount material 13, and the light emitting element 14 is thus mounted on the first lead portion 11. Moreover, a back surface of the light emitting element 14 is conductive with the first lead portion 11 via the die-mount material 13. The light emitting element 14 is, for example, an element formed by stacking semiconductor layers made of gallium nitride (GaN) and the like on a sapphire substrate. The light emitting element 14 has, for example, a rectangular solid shape, and a terminal 14b is provided on an upper surface thereof. The light emitting element 14 emits, for example, blue light when a voltage is supplied between the terminal 14b and the back surface of the light emitting element 14.

An end of a wire 16 is bonded to the terminal 14b of the light emitting element 14. The wire 16 is lead out in the +Z direction from the terminal 14b, and is curved in a direction between the +X direction and the −Z direction. The other end of the wire 16 is bonded to the upper surface 12h of the second lead portion 12. Thus, the terminal 14b is connected to the second lead portion 12 via the wire 16. The wire 16 is made of metal such as gold or aluminum.

The light emitting device 1 is provided with the first resin body 171. The first resin body 171 is made of a transparent resin (translucent resin) such as a silicone resin. Note that “transparent” also includes semitransparent. The external shape of the first resin body 171 is a rectangular solid, and is provided to cover the light emitting element 14, the wire 16, the surface 11h of the first lead portion 11, and the surface 12h of the second lead portion 12 on the first main surface s1 side of the first lead portion 11 and the second lead portion 12. In addition, the first resin body 171 is embedded in the recess portions DP provided in the side surfaces 11s of the first lead portion 11 and the side surfaces 12s of the second lead portion 12.

Moreover, the light emitting device 1 is provided with the second resin body 172. The second resin body 172 is made of a resin such as a silicone resin including the phosphor leighthe second resin body 172 is provided to cover the exterior of the first resin body 171 from the first main surface s1 side to at least a position of the lowermost end of the recess portions DP in a direction orthogonal to the first main surface s1. In this respect, the position of the lowermost end means a position which is farthest from the first main surface s1 among positions on each recess portion DP in the Z direction. In this specific example, the positions on the recess portions DP in the Z direction spread from the first main surface s1 to a second main surface s2. Accordingly, the position of the lowermost end is the position of the second main surface s2.

In this specific example, the second resin body 172 covers a top surface 171a and side surfaces 171b of the first resin body 171, the side surfaces 11s of the first lead portion 11, and the side surfaces 12s of the second lead portion 12, as well as reaches the position of the second main surface s2.

To be more specific, in the lower surface 11f of the first lead portion 11, the lower surface of the protrusion 11g is exposed from a lower surface of the first resin body 171. Meanwhile, the entire upper surface 11h of the first lead portion 11, the regions other than the protruding portion 11g in the lower surface 11f, the entire upper surface 12h of the second lead portion 12, and regions other than the protruding portion 12g in the lower surface 12f are covered with the first resin body 171. In addition, the top surface 171a and the side surfaces 171b of the first resin body 171, front end surfaces of the hanging pins 11b to 11e, and front end surfaces of the hanging pins 12b to 12e are covered with the second resin body 172. In the light emitting device 1, the lower surfaces of the protruding portions 11g, 12g exposed from the lower surface of the first resin body 171 serve as external electrode pads.

In this respect, the second resin body 172 includes a large number of particles of the phosphor leighthe phosphor 18 is granular, absorbs light emitted from the light emitting element 14, and emits light with a wavelength longer than the absorbed light. For example, the phosphor 18 absorbs part of the blue light emitted from the light emitting element 14, and emits yellow light. Thus, the blue light transmitting through the second resin body 172 and the yellow light resulting from the wavelength conversion by the phosphor 18 are combined, and white light is obtained. Note that the wavelength of the light emitted from the light emitting element 14 and the wavelength of the light resulting from the conversion by the phosphor 18 are not limited to those described above.

The second resin body 172 has a uniform thickness. In other words, the thickness of a portion of the second resin body 172 covering the top surface 171a of the first resin body 171 in the Z direction is equal to the thickness of portions of the second resin body 172 covering the side surfaces 171b of the first resin body 171 in the X direction and the Y direction.

In the light emitting device 1 according to this embodiment, since the second resin body 172 has the uniform thickness as described above, the difference in the distance that the light travels through the second resin body 172 becomes smaller among various angles at which the light is radially emitted from the light emitting device 14. Thus, variation in the wavelength conversion by the phosphor 18 is suppressed among the various angles at which the light is emitted radially, and dependency of the chromaticity of the emitted light on its angle is suppressed.

Moreover, as shown in FIG. 3A, since the light emitting device 1 is covered with the second resin body 172 to the position of the lowermost end of the recess portions DP, light leaking to the outside from the recess portions DP also travels through the second resin body 172. Thus, the light leaking from the recess portions DP are also subjected to the wavelength conversion by the phosphor 18.

In addition, as shown in FIG. 3B, since the side surfaces of the first resin body 171 embedded in a space SL between the first lead portion 11 and the second lead portion 12 is also covered with the second resin body 172, light leaking from the space SL between the first lead portion 11 and the second lead portion 12 also travels through the second resin body 172 as well. Thus, the light leaking from the space SL between the first lead portion 11 and the second lead portion 12 are also subjected to the wavelength conversion by the phosphor 18.

In addition, since the side surfaces 11s of the first lead portion 11 and the side surfaces 12s of the second lead portion 12, that is to say, the front end surfaces of the hanging pins 11b to 11e, 12b to 12e are covered with the second resin body 172, corrosion of the first lead portion 11 and the second lead portion 12 which occurs from these surfaces is prevented.

Next, a method of manufacturing the light emitting device according to this embodiment will be described.

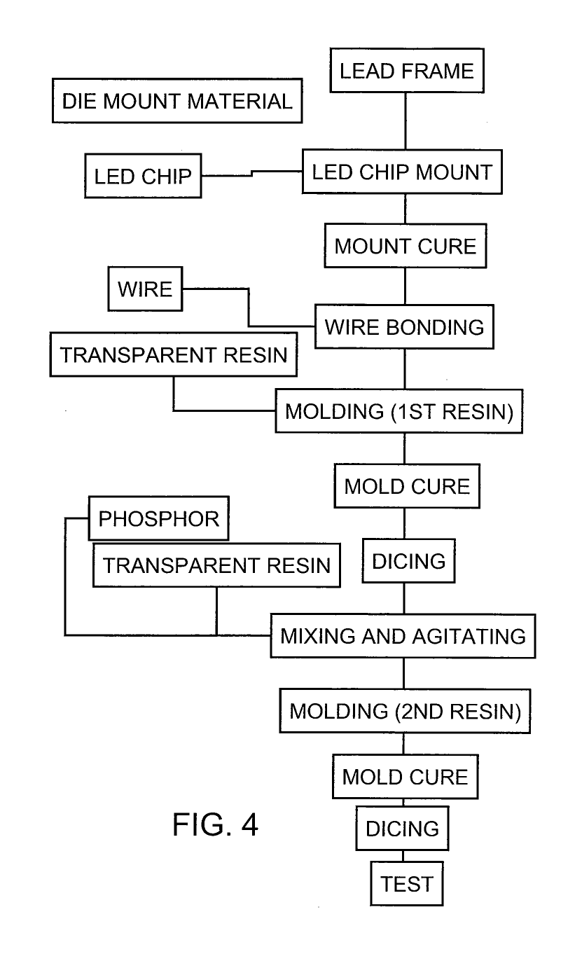

FIG. 4 is a flowchart illustrating the method of manufacturing the light emitting device according to this embodiment.

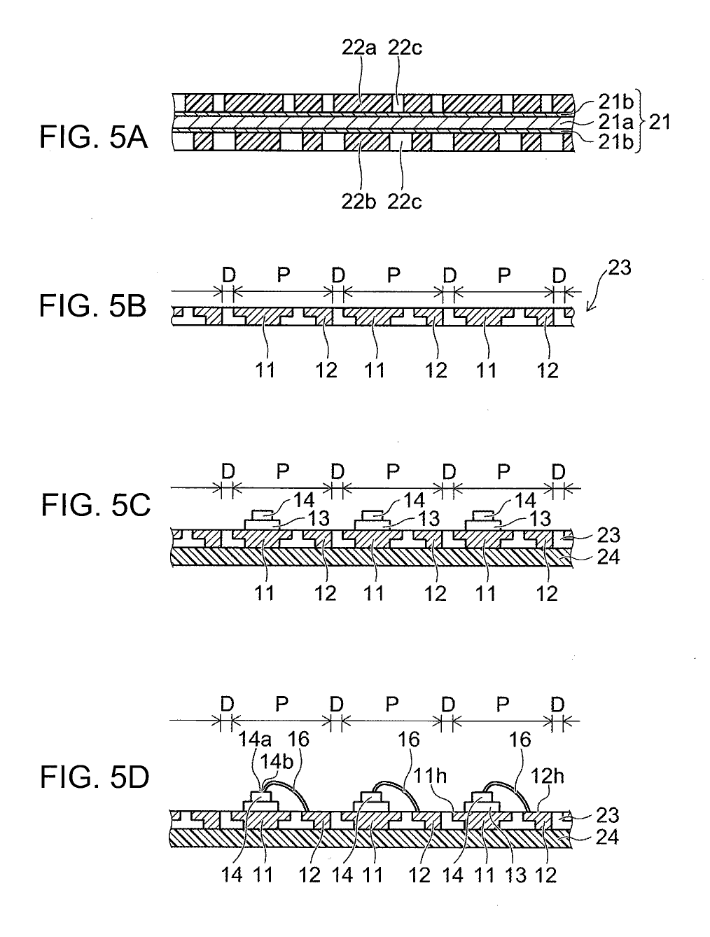

FIGS. 5A to 10B are cross-sectional views illustrating steps in the method of manufacturing the light emitting device according to this embodiment.

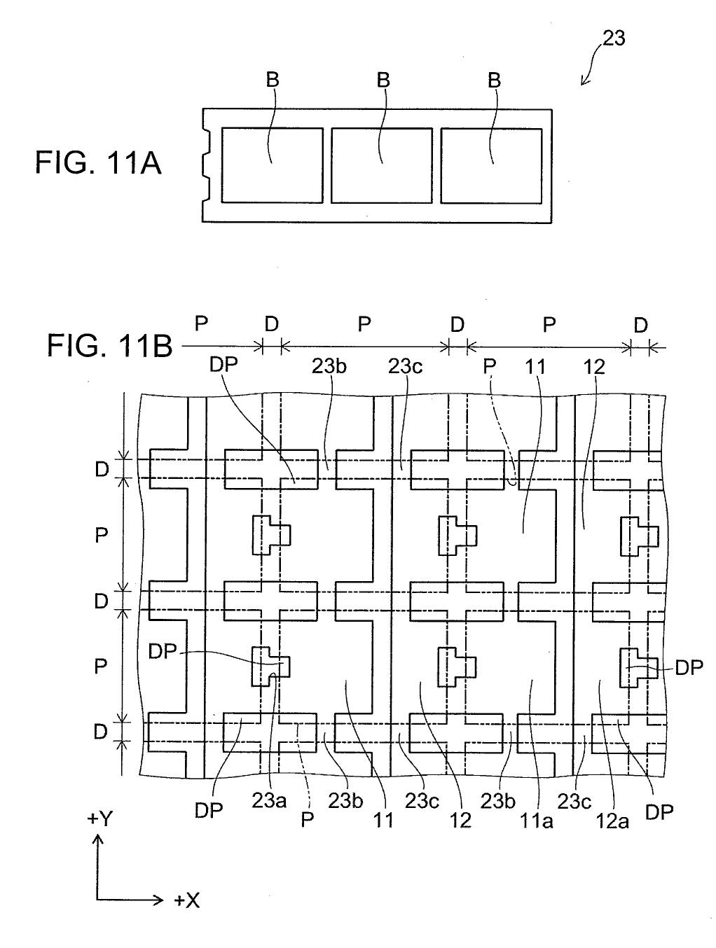

FIG. 11A is a plan view illustrating the lead frame in this embodiment. FIG. 11B is a partially enlarged plan view illustrating element regions in the lead frame.

Firstly, as shown in FIG. 5A, an electrically conductive sheet 21 made of electrically conductive material is prepared. The electrically conductive sheet 21 is, for example, a strip-shaped copper plate 21a provided with silver plating layers 21b on the upper and lower surfaces thereof. Next, masks 22a, 22b are formed on the upper and lower surfaces of the electrically conductive sheet 21. The masks 22a, 22b have opening portions 22c selectively formed therein. The masks 22a, 22b are formed by printing, for example.

Subsequently, the electrically conductive sheet 21 covered with the masks 22a, 22b is subjected to wet etching by being immersed in an etchant. Thus, portions of the electrically conductive sheet 21 which are in the opening portions 22c are etched away and selectively removed. At this time, the etching amount is controlled by, for example, adjusting the immersing time. Thus, the etching is stopped before the etching from each of the upper surface and the lower surface of the electrically conductive sheet 21 penetrates the electrically conductive sheet 21 singly. Thereby, half etching is performed from both the upper surface and the lower surface. Note that portions etched from both the upper surface and the lower surface penetrate the electrically conductive sheet 21. Thereafter, the masks 22a and 22b are removed.

Subsequently, as shown in FIGS. 4 and 5B, parts of the copper plate 21a and parts of the silver plating layers 21b are selectively removed from the electrically conductive sheet 21, and thus a lead frame 23 is formed. Note that for the convenience of illustration, the copper plate 21a and the silver plating layers 21b are integrally illustrated as the lead frame 23 in FIG. 5B and the subsequent drawings without distinguishing between the copper plate 21a and the silver plating layers 21b. As shown in FIG. 11A, for example, three blocks B are set in the lead frame 23. In each block B, approximately 1000 element regions P are set up, for example. As shown in FIG. 11B, the element regions P are arranged in a matrix, and a region between each two adjacent element regions P serves as a dicing region D. In each element region P, a basic pattern including the first lead portion 11 and the second lead portion 12 which are spaced apart from each other is formed. In the dicing region D, the electrically conductive material constituting the electrically conductive sheet 21 is left to connect the adjacent element regions P.

In other words, although the first lead portion 11 and the second lead portion 12 are disposed away from each other in each of the element regions P, the first lead portion 11 belonging to any element region P is connected to the second lead portion 12 belonging to an adjacent element region P in −X direction. An opening portion 23a having a square-on-rectangle shape which faces in the +X direction is formed between each two adjacent frames. Moreover, the first lead portions 11 belonging to each two adjacent element regions P in the Y direction are connected to each other via a bridge 23b. Similarly, the second lead portions 12 belonging to each two adjacent element regions P in the Y direction are connected to each other via a bridge 23c. Accordingly, four conductive members extend out in three directions from the base portion 11a of each first lead portion 11 and from the base portion 12a of each second lead portion 12. Spaces provided in the openings 23a and spaces between bridges 23b, 23c serve as the recess portions DP provided in the side surfaces of the leads 10.

Thereafter, the lead frame 23 is half-etched from the lower surface, and the protruding portions 11g, 12g (see FIG. 2) are respectively formed on the lower surfaces of the first lead portion 11 and the second lead portion 12.

Next, as shown in FIGS. 4 and 5C, a reinforcing tape 24 made of, for example, polyimide is attached to the lower surface of the lead frame 23. Then, the die-mount material 13 is applied onto the first lead portion 11 of each element region P of the lead frame 23. For example, the die-mount material 13 in paste form is discharged from a discharger onto the first lead portion 11, or is transferred onto the first lead portion 11 by mechanical means. Next, the light emitting element 14 is mounted on the die-mount material 13. Thereafter, heat treatment (mount curing) to sinter the die-mount material 13 is preformed. Thus, the light emitting element 14 is mounted on the first lead portion 11 with the die-mount material 13 interposed in between in each element region P of the lead frame 23.

Next, as shown in FIGS. 4 and 5D, ends of the wires 16 are bonded to the terminals 14b of the corresponding light emitting elements 14, and the other ends thereof are bonded to the upper surfaces 12h of the corresponding second lead portions 12, respectively, by ultrasonic bonding. Thus, the terminals 14b are connected to the second lead portions 12 via the wires 16, respectively.

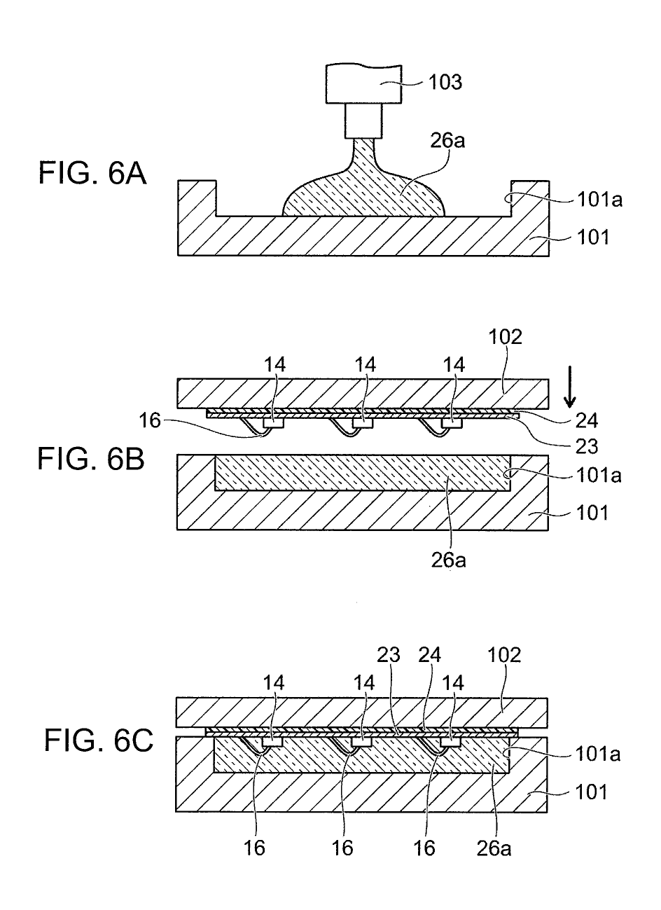

Next, as shown in FIGS. 4 and 6A, a mold 101 is prepared. A recess portion 101a having a rectangular solid shape is formed in an upper surface of the mold 101. A transparent resin (first resin) 26a such as a silicone resin is supplied into the recess portion 101a of the mold 101 with a dispenser 103.

Next, as shown in FIGS. 4 and 6B, the above-described lead frame 23 on which the light emitting elements 14 are mounted is attached to a lower surface of a dicing sheet 102 in a manner that the light emitting elements 14 face downward. Then, the dicing sheet 102 is pressed on the mold 101. At this time, the transparent resin 26a covers the light emitting elements 14 and the wires 16, and enters the portions in the lead frame 23 which have been removed by etching. Thus, the transparent resin 26a is molded.

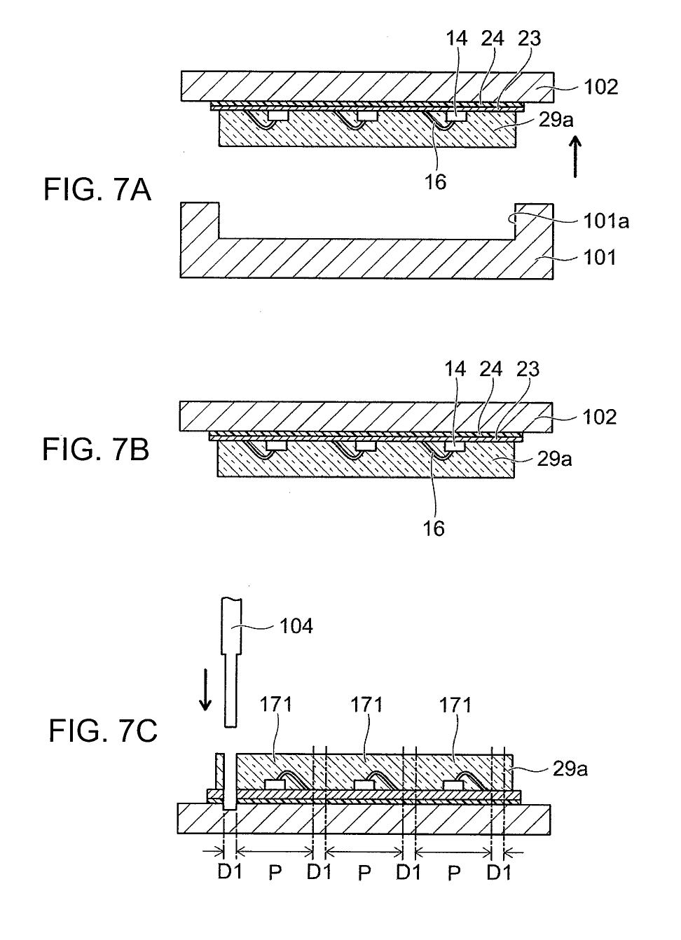

Thereafter, as shown in FIGS. 4 and 6C, heat treatment (mold curing) is performed while an upper surface of the lead frame 23 is pressed against the transparent resin 26a, and thus the transparent resin 26a is cured. Then, as shown in FIG. 7A, the dicing sheet 102 is pulled away from the mold 101. Thus, as shown in FIG. 7B, a transparent resin plate 29a is formed on the lead frame 23, the transparent resin plate 29a covering the entire upper surface and part of the lower surface of the lead frame 23, and having the light emitting elements 14 and the like embedded therein.

Next, as shown in FIGS. 4 and 7C, a combined body including the lead frame 23 and the transparent resin plate 29a is diced from the transparent resin plate 29a side with a blade 104. In this case, the blade 104 cuts into the combined body to an upper-surface-side portion of the dicing sheet 102. The cuts thus formed allow a material of the second resin body 172 to surround portions defined by the cuts in a step described later.

Portions of the lead frame 23 and the transparent resin plate 29a which are disposed in dicing regions D1 are removed by the dicing. As a result, portions of the lead frame 23 and the transparent resin plate 29a which are disposed in the element regions P are formed into individual pieces, and thus the first resin element bodies 171, the first lead portions 11, and the second lead portions 12 as shown in FIGS. 1 to 3 are manufactured. Moreover, the bridges 23b, 23c are cut, and the hanging pins 11b to 11e, 12b to 12e are formed. The space between each two adjacent hanging pins 11b to 11e, 12b to 12e serves as the recess portion DP. The first resin bodies 171 are embedded also in the recess portions DP. Here, the width of each of the portions from which the transparent resin plate 29a is removed with the blade 104 is D1.

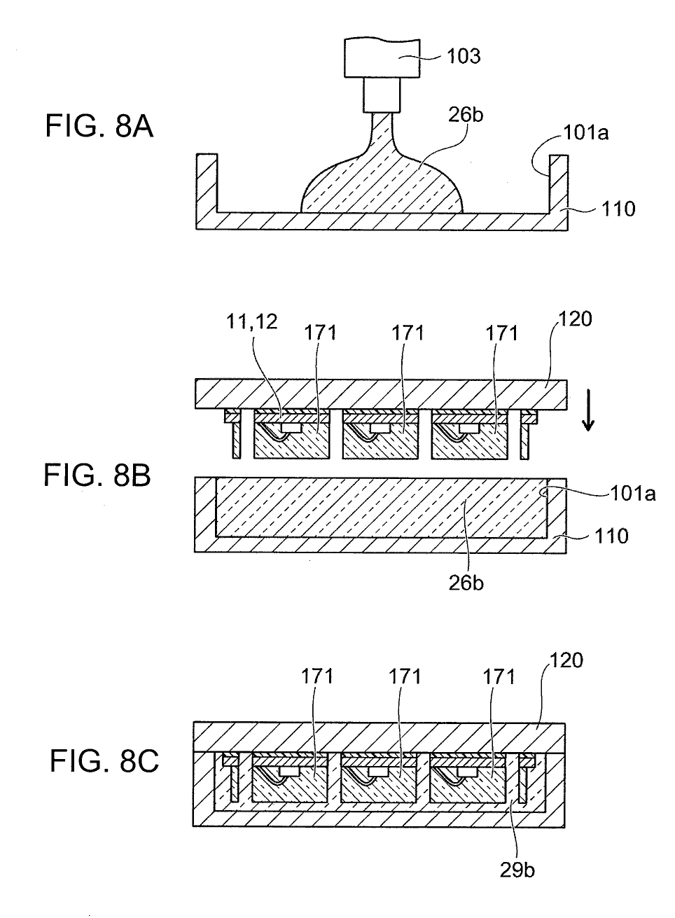

After the individual pieces are formed by the dicing, the dicing sheet 102 is removed, and another dicing sheet 120 (see FIG. 8B) is attached. In the surface of the dicing sheet 102, cuts are formed by the dicing previously performed. When the resin material of the second resin bodies 172 enters these cuts in the subsequent step, flash may be formed in these portions. In order to prevent the formation of flash, the dicing sheet 102 is replaced with the other dicing sheet 120.

The dicing sheet is replaced as follows. Firstly, the top surfaces of the first resin bodies 171 are attached to an adhesive sheet or a workbench with adhesiveness, and the first resin bodies 171 are fixed thereto. Then, the dicing sheet 102 attached to the first lead portions 11 and the second lead portions 12 is peeled off. Thereafter, the new dicing sheet 120 is attached to the first lead portions 11 and the second lead portions 12. Subsequently, the adhesive sheet or the workbench attached to the top surfaces of the first resin bodies 171 is peeled off.

Subsequently, as shown in FIGS. 4 and 8A, a mold 110 is prepared. A recess portion 110a having a rectangular solid shape is formed in an upper surface of the mold 110. Meanwhile, a phosphor-containing resin material (second resin) 26b in liquid or semi-liquid form is prepared by mixing a transparent resin such as a silicone resin with the phosphor 18 (see FIG. 2), and then agitating the mixture. Then, the phosphor-containing resin material 26b is supplied into a recess portion 110a of a mold 110 with the dispenser 103.

Next, as shown in FIGS. 4 and 8B, the first lead portions 11 and the second lead portions 12 to which the dicing sheet 120 is attached are disposed in a manner that the first resin bodies 171 face downward. Then, the dicing sheet 120 is pressed on the mold 110. At this time, the phosphor-containing resin material 26b covers the first resin bodies 171, and enters the interstices between the adjacent first resin bodies 171 (the portions which have been removed by the blade 104). Thus, the phosphor-containing resin material 26b is molded.

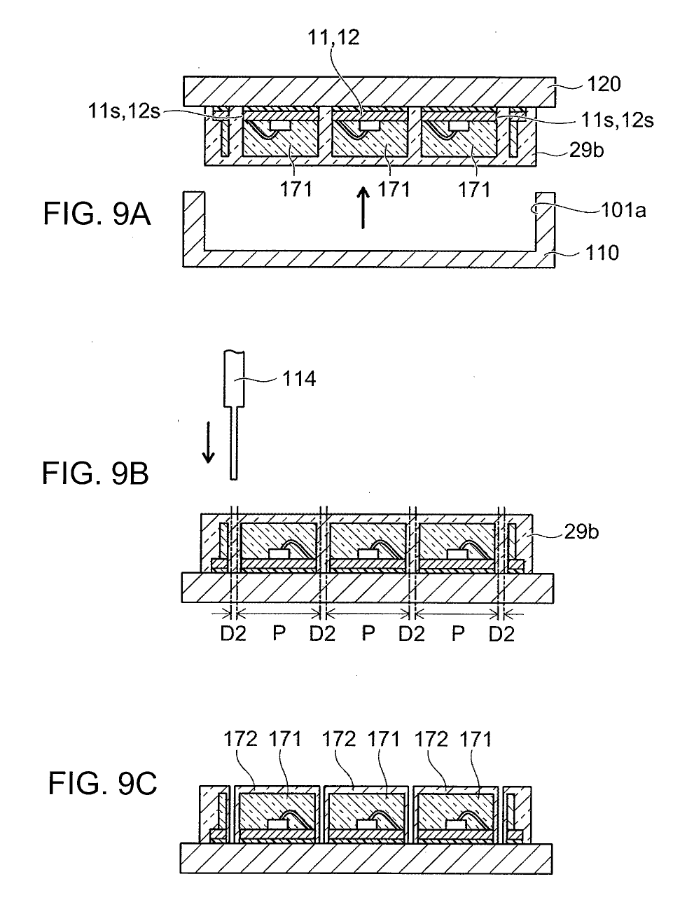

Next, as shown in FIGS. 4 and 8C, heat treatment (mold curing) is performed while the upper surfaces of the first lead portions 11 and the second lead portions 12 are pressed against the phosphor-containing resin material 26b, and thus the phosphor-containing resin material 26b is cured. Then, as shown in FIGS. 4 and 9A, the dicing sheet 120 is pulled away from the mold 110. Thus, as shown in FIGS. 4 and 9B, a phosphor-containing resin plate 29b is formed on the dicing sheet 120, the phosphor-containing resin plate 29b covering the top surfaces and side surfaces of the first resin bodies 171, the side surfaces 11s of the first lead portions 11, the side surfaces 11s of the second lead portions 12.

Subsequently, as shown in FIGS. 4 and 9B, the phosphor-containing resin plate 29b is diced with a blade 114. Note that the width of the blade 114 (width of cut) is smaller than the width of the blade 104 used in the previous dicing. By this dicing, portions disposed in dicing regions D2 of the phosphor-containing resin plate 29b is removed as shown in FIG. 9C. As a result, the phosphor-containing resin plate 29b is divided into individual pieces, and thus the second resin bodies 172 as shown in FIGS. 1 to 3 is manufactured. The width of each of the portions from which the phosphor-containing resin plate 29b is removed with the blade 114 is D2.

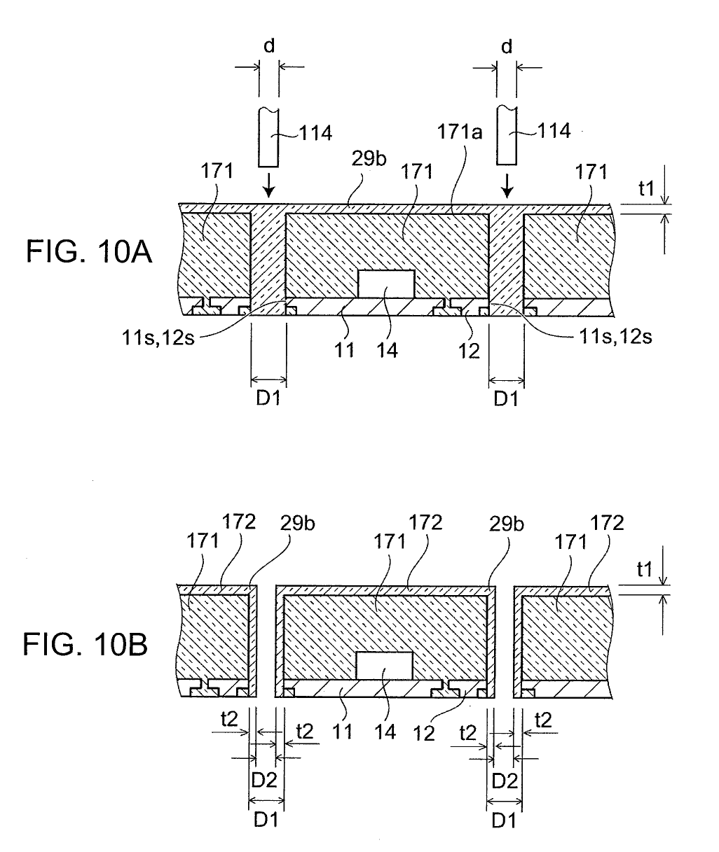

How the phosphor-containing resin plate 29b is removed with the blade 114 will be described. FIG. 10A is a partially enlarged schematic cross-sectional view illustrating a state where the phosphor-containing resin plate 29b is formed. The phosphor-containing resin plate 29b is provided to cover the top surfaces and side surfaces of the first resin bodies 171, the side surfaces 11s of the first lead portions 11, and the side surfaces 12s of the second lead portions 12. On this occasion, the phosphor-containing resin plate 29b is formed on the top surfaces 171a of the first resin bodies 171 with a thickness t1. The thickness t1 is accurately set according to the difference between the depth of the recess portion 110a of the mold 110 and the depth of the recess portion 101a of the mold 101. Moreover, the phosphor-containing resin plate 29b is provided in the regions between the adjacent first resin bodies 171, each region having a width D1. The width D1 is set in accordance with the width of the blade 104 used to cut the transparent resin plate 29a.

The phosphor-containing resin plate 29b is cut with the blade 114 at positions between the adjacent first resin bodies 171. The width d of the blade 114 is smaller than the width D1 of the phosphor-containing resin plate 29b between the adjacent first resin bodies 171. The width D2 of the cuts formed in the phosphor-containing resin plate 29b is set in accordance with the width d of the blade 114.

FIG. 10B is a partially enlarged schematic cross-sectional view illustrating a state in which the phosphor-containing resin plate 29b has been divided. The dividing of the phosphor-containing resin plate 29b with the blade 114 is performed in a manner that the phosphor-containing resin plate 29b remains with the same width on both sides of the blade 114. Portions where the phosphor-containing resin plate 29b remains serve as the second resin bodies 172.

The width t2 of the remaining phosphor-containing resin plate 29b is equal to the thickness t1 of the phosphor-containing resin plate 29b provided on the top surfaces 171a of the first resin bodies 171.

In other words, when the phosphor-containing resin plate 29b is divided with the blade 114, the second resin bodies 172 are formed into such individual pieces that the thickness thereof on the top surface 171a side of the first resin body 171 is equal to the thickness thereof on the side surface 171b side of the first resin body 171. In order to form the second resin bodies 172 as described above by cutting the phosphor-containing resin plate 29b with the blade 114, the width D1 between the adjacent first resin bodies 171 is set as follows:

D1=2×t2+D2

where t2 denotes the width of the portion of the second resin body 172 remaining on the side surface 171b of each of the first resin bodies 171, and d2 denotes the width of the cuts formed with the blade 114 to divide the phosphor-containing resin plate 29b.

According to the method of manufacturing the light emitting device 1 of this embodiment, the width D1 between the adjacent first resin bodies 171 is set at the value described above. Then, the cutting is performed with the center of the width D1 and the center of the blade 114 aligned with each other. Thus, simultaneously with the cutting of the phosphor-containing resin plate 29b with the blade 114, the second resin bodies 172 with the uniform thickness are formed. The second resin bodies 172 thus formed each cover the outside of the corresponding first resin body 171 from the first main surface s1 side to at least the position of the lowermost end of the recess portions DP.

In each of the light emitting devices 1 thus manufactured, the difference in the distance that the light travels through the second resin body 172 becomes smaller among various angles at which the light is radially emitted from the light emitting device 14. Thus, variation in the wavelength conversion by the phosphor 18 is suppressed among the various angles at which the light is emitted radially, and dependency of the chromaticity of the emitted light on its angle is suppressed.

Moreover, since the light emitting device 1 is covered with the second resin body 172 to the position of the lowermost end of the recess portions DP, light leaking to the outside from the recess portions DP also travels through the second resin body 172. Thus, the light leaking from the recess portions DP are also subjected to the wavelength conversion by the phosphor 18.

In addition, since the side surfaces 171b of the first resin body, the side surfaces 11s of the first lead portion 11, and the side surfaces 12s of the second lead portion 12 are covered with the second resin body 172, light leaking from the space between the first lead portion 11 and the second lead portion 12 also travels through the second resin body 172. Thus, the light leaking from the space SL between the first lead portion 11 and the second lead portion 12 are also subjected to the wavelength conversion by the phosphor 18. Moreover, since the side surfaces 11s of the first lead portion 11 and the side surfaces 12s of the second lead portion 12, that is to say, the front end surfaces of the hanging pins 11b to 11e, 12b to 12e are covered with the second resin body 172, corrosion of the first lead portion 11 and the second lead portion 12 which occurs from these surfaces is prevented.

Next, a first modification of the first embodiment will be described.

This modification is a modification of the method of forming the lead frame.

Specifically, this modification is different from the first embodiment described above in the method of forming the lead frame shown in FIG. 5A.

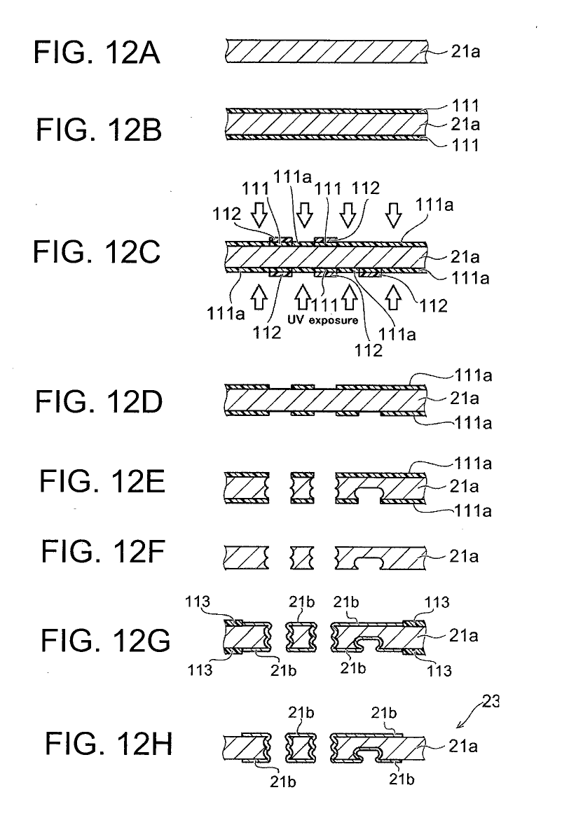

FIGS. 12A to 12H are cross-sectional views illustrating steps in the method of forming the lead frame according to this modification.

Firstly, as shown in FIG. 12A, a copper plate 21a is prepared and cleaned. Then, as shown in FIG. 12B, resist coating is applied to both surfaces of the copper plate 21a, and is then dried to form resist films 111.

Next, as shown in FIG. 12C, mask patterns 112 are placed on the resist films 111, respectively, and the resist films 111 are irradiated with ultraviolet light for exposure. Thus, exposed portions of the resist films 111 are cured, and resist masks 111a are formed.

Subsequently, as shown in FIG. 12D, development is performed, and uncured portions of the resist films 111 are washed away. Thus, the resist patterns 111a remain on the upper and lower surfaces of the copper plate 21a, respectively.

Thereafter, as shown in FIG. 12E, etching is performed using the resist patterns 111a as masks, and exposed portions of the copper plate 21a are removed from both surfaces of the copper plate 21a. At this time, an etching depth is set at a value approximately the half of that of the thickness of the copper plate 21a. Accordingly, regions which are etched only from one side are half-etched, and regions which are etched from both sides are penetrated.

Next, as shown in FIG. 12F, the resist patterns 111a are removed. Then, as shown in FIG. 12G, end portions of the copper plate 21a are covered with masks 113, and the copper plate 21a is then plated. Thus, a silver plating layer 21b is formed on surfaces of portions of the copper plate 21a other than the end portions.

Thereafter, as shown in FIG. 12H, the copper plate 21a is cleaned and the masks 113 are removed. Then, inspection is performed. Thus, the lead frame 23 is produced. The configuration, manufacturing method, and operational effects of this modification which are other than those described above are the same as those of the first embodiment described above.

Next, descriptions will be provided for a second modification of the first embodiment.

This modification is a modification of the method of manufacturing the light emitting device.

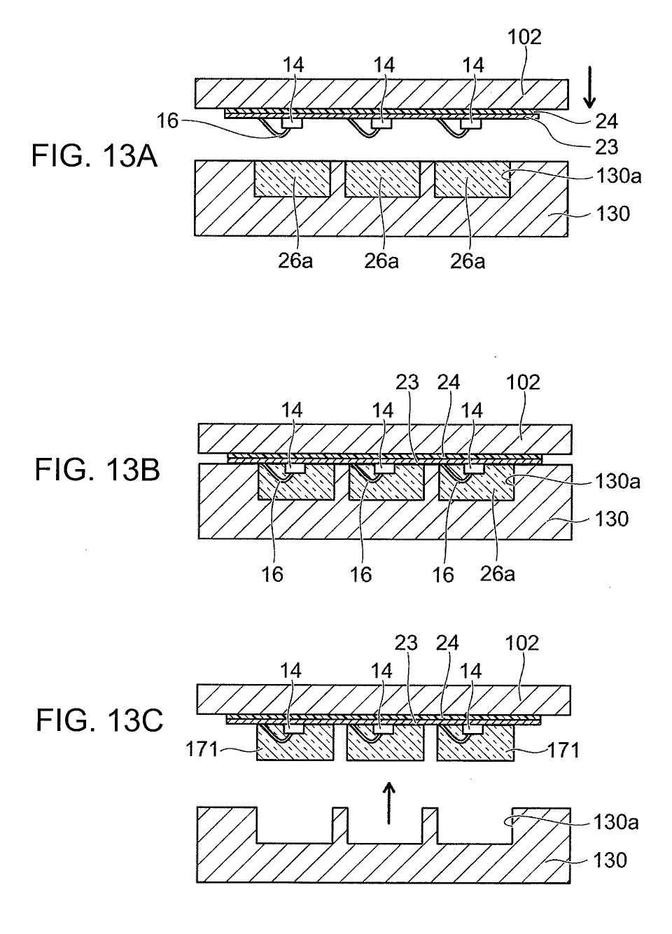

FIGS. 13A to 15B are cross-sectional views illustrating steps in a method of manufacturing a light emitting device according to this modification.

In this modification, molds 130, 140 are used to form the first resin bodies 171.

In this respect, steps up to the mounting of light emitting elements 14 on first lead portions 11 and second lead portions 12, and the connection of the wires 16 to the first lead portions 11 and the second lead portions 12 are the same as the steps illustrated in FIGS. 5A to 5D. After the mounting of the light emitting elements 14 on the first lead portions 11 and the second lead portions 12 as well as the bonding of the wires 16 thereto, the mold 130 is prepared as shown in FIG. 13a. Multiple recess portions 130a are formed in an upper surface of the mold 130, the recess portions 130a each having a rectangular solid shape. In other words, each of the recess portions 130a of the mold 130 is provided matching the external shape of a first resin body 171. For the purpose of forming multiple first resin bodies 171, the multiple recess portions 130a are provided matching the respective multiple first resin bodies 171. A transparent resin (first resin) 26a such as a silicone resin is supplied into the recess portions 130a with a dispenser 103.

Next, a lead frame 23 on which the light emitting elements 14 are mounted is attached to the lower surface of a dicing sheet 102 in a manner that the light emitting elements 14 face downward. Then, as shown in FIG. 13B, the dicing sheet 102 is pressed on the mold 130. At this time, the light emitting elements 14 and the wires 16 are embedded in the transparent resin 26a supplied into the recess portions 130a. Thus, the transparent resin 26a is molded.

Thereafter, heat treatment (mold curing) is performed while the upper surface of the lead frame 23 is pressed against the transparent resin 26a, and thus the transparent resin 26a is cured. Then, as shown in FIG. 13C, the dicing sheet 102 is pulled away from the mold 130. Thus, formed are the first resin bodies 171 which cover the light emitting elements 14 and the wires 16 mounted on the lead frame 23. The shapes of the recess portions 130a of the mold 130 are transferred onto the first resin bodies 171 as their external shapes. Thereafter, the lead frame 23 is cut in accordance with the first resin bodies 171, and the first lead portions 11 and the second lead portions 12 are formed.

In this respect, the lead frame 23 is cut in a following way. Firstly, the top surfaces of the first resin bodies 171 are attached to an adhesive sheet or a workbench with adhesiveness, and the first resin bodies 171 are fixed thereto. Then, the dicing sheet 102 is peeled off. In this state, the lead frame 23 which is exposed is cut along the external shapes of the first resin bodies 171, and thus the first lead portions 11 and the second lead portions 12 are formed. Thereafter, the new dicing sheet 120 is attached to the first lead portions 11 and the second lead portions 12. Subsequently, the adhesive sheet or the workbench attached to the top surfaces of the first resin bodies 171 is peeled off.

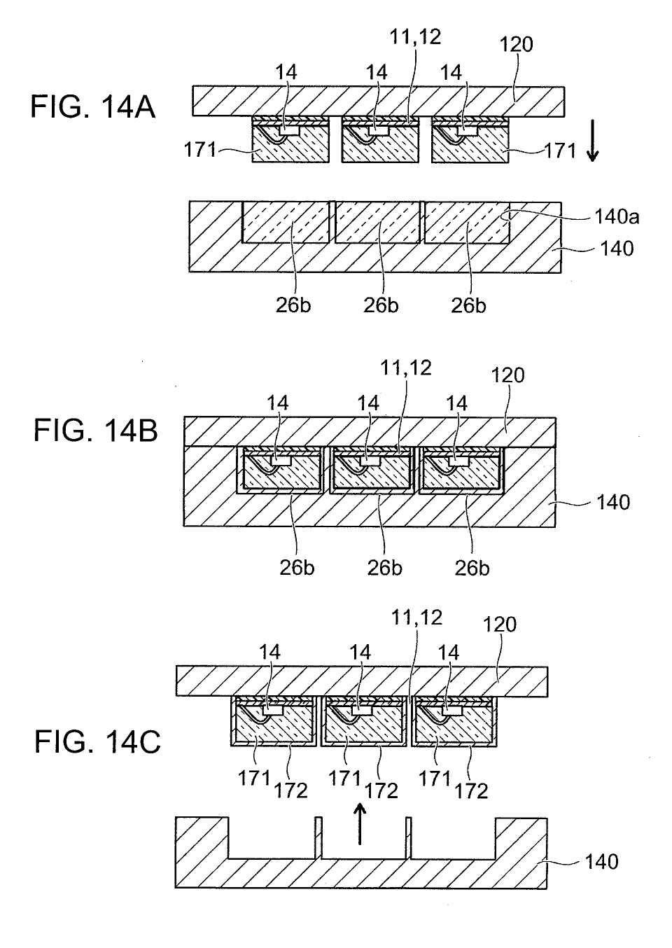

Subsequently, the mold 140 is prepared as shown in FIG. 14a. Multiple recess portions 140a are formed in an upper surface of the mold 140, the recess portions 140a each having a rectangular solid shape. In other words, each of the recess portions 140a of the mold 140 is provided matching the external shape of the second resin body 172. For the purpose of forming multiple second resin bodies 172, the multiple recess portions 140a are provided matching the respective multiple second resin bodies 172. The phosphor-containing resin material 26b is supplied into the recess portions 140a with the dispenser 103.

Next, the first lead portions 11 and the second lead portions 12 on which the dicing sheet 120 is attached are placed in a manner that the first resin bodies 171 face downward. Subsequently, the dicing sheet 120 is pressed on the mold 140. On this occasion, the phosphor-containing resin material 26b covers the first resin bodies 171, and enters the interstices between the adjacent first resin bodies 171 as well. Thus, the phosphor-containing resin material 26b is molded.

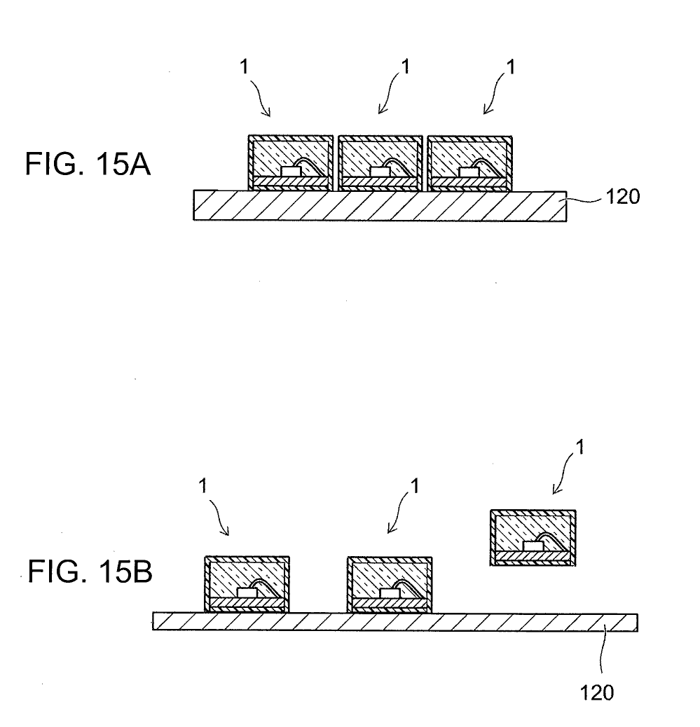

Thereafter, as shown in FIG. 14B, heat treatment (mold curing) is performed while the upper surfaces of the first lead portions 11 and the second lead portions 12 are pressed against the phosphor-containing resin material 26b. Thus, the phosphor-containing resin material 26b is cured. Then, as shown in FIG. 14C, the dicing sheet 120 is pulled away from the mold 140. Thus, as shown in FIG. 15A, formed are the light emitting devices 1, in each of which the second resin body 172 covering the top surface and side surfaces of the first resin body 171, as well as the side surfaces 11s of the first lead portion 11 and the side surfaces 12s of the second lead portion 12 is formed. The external shapes of the second resin bodies 172 are formed by transferring the shapes of the recess portions 140a of the mold 140.

Next, as shown in FIG. 15B, the dicing sheet 120 is stretched. Thus, intervals between the multiple light emitting devices 1 on the dicing sheet 120 are increased. Then, the light emitting devices 1 are removed from the dicing sheet 120 one by one.

According to this manufacturing method, the first resin bodies 171 and the second resin bodies 172 are accurately molded by using the molds 130, 140. Moreover, the thickness of the second resin bodies 172 is accurately set by using the molds 130, 140. Furthermore, the first resin bodies 171 and the second resin bodies 172 are formed without performing cutting by a blade.

### Second Embodiment

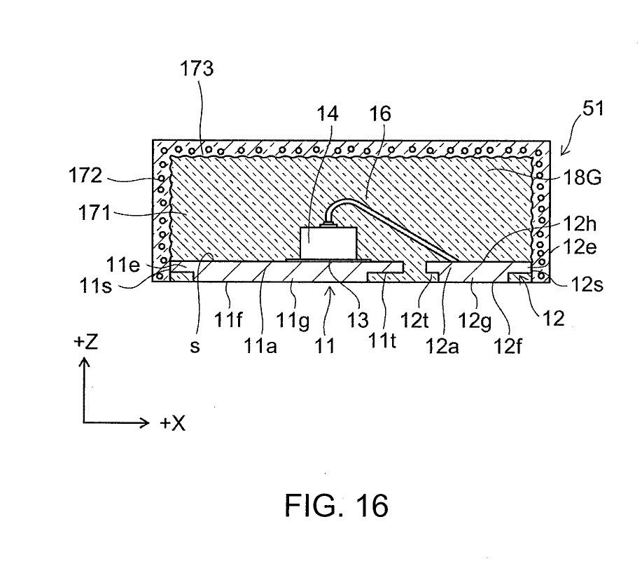

FIG. 16 is a cross-sectional view illustrating a light emitting device according to a second embodiment.

As shown in FIG. 16, a light emitting device 51 according to this embodiment includes: a first lead portion 11 and a second lead portion 12 making a pair; a light emitting element 14 mounted on a base portion 11a on a first main surface s1 of the first lead portion 11 and the second lead portion 12; a first resin body 171 provided on the first main surface s1 side of the first lead portion 11 and the second lead portion 12 and covering the light emitting element 14; and a second resin body 172 covering a top surface 171a and side surfaces 171b of the first resin body 171, side surfaces 11s of the first lead portion 11, and side surfaces 12s of the second lead portion 12. Moreover, the light emitting device 51 has unevenness 173 in an interface between the first resin body 171 and the second resin body 172.

The unevenness 173 is provided by subjecting the top surface 171a and the side surfaces 171b of the first resin body 171 to satin processing, for example.

In the light emitting device 51, the provision of the unevenness 173 suppresses total reflection of light by the interface between the first resin body 171 and the second resin body 172, compared to a case where the interface is a flat surface. Moreover, the provision of the unevenness 173 increases the contact area between the first resin body 171 and the second resin body 172, and thus adhesion therebetween is improved.

Next, an example of a method of manufacturing the light emitting device 51 according to this embodiment will be described.

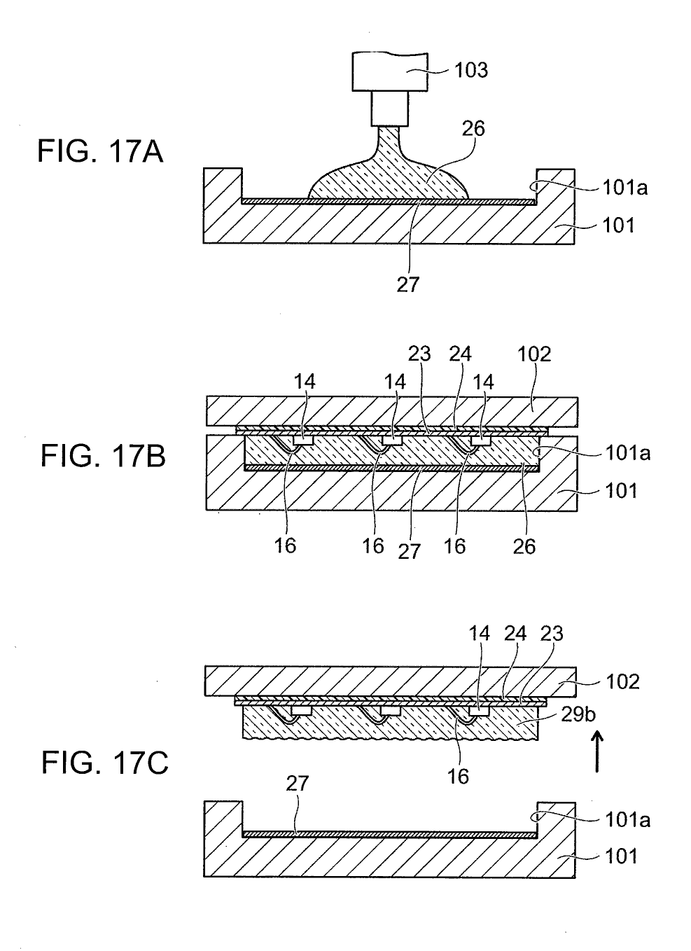

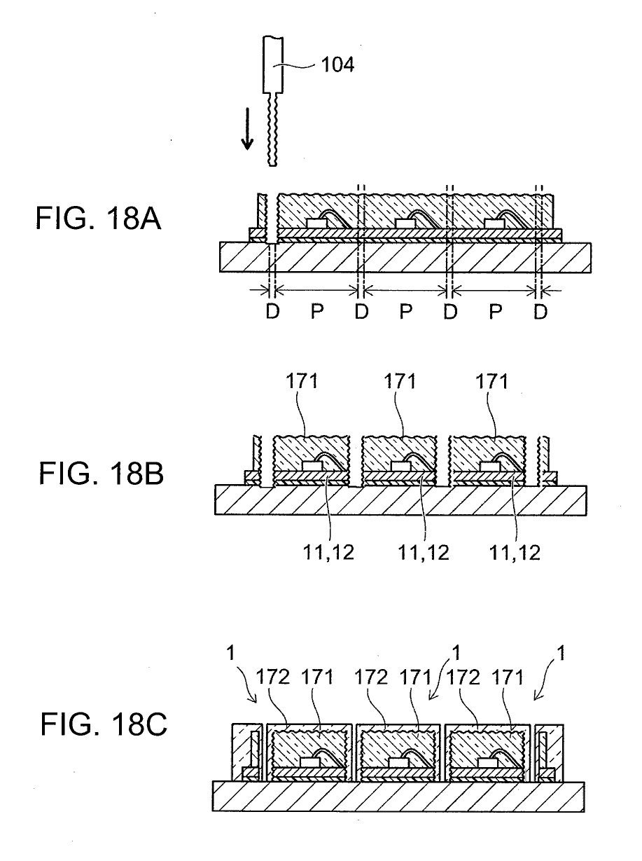

FIGS. 17A to 18C are cross-sectional views illustrating steps in the method of manufacturing the light emitting device according to this embodiment.

First of all, as shown in FIG. 17A, a mold 101 is prepared. A recess portion 101a having a rectangular solid shape is formed in an upper surface of the mold 101. A sheet 27 having an uneven surface is arranged in the bottom of this recess portion 101a. On the other hand, a transparent resin (first resin) 26a such as a silicone resin is supplied into the recess portion 101a of the mold 101 with a dispenser 103.

Next, as shown in FIG. 17B, a lead frame 23 on which light emitting elements 14 are mounted is attached to a lower surface of a dicing sheet 102 in a manner that the light emitting elements 14 face downward. Then, the dicing sheet 102 is pressed on the mold 101. Thereby, the transparent resin 26a covers the light emitting elements 14 and wires 16. Thus, the transparent resin 26a is molded.

Thereafter, heat treatment (mold curing) is performed while an upper surface of the lead frame 23 is pressed against the transparent resin 26a, and thus the transparent resin 26a is cured. Then, as shown in FIG. 17C, the dicing sheet 102 is pulled away from the mold 101. Thus, a transparent resin plate 29a is formed on the lead frame 23, the transparent resin plate 29a covering the entire upper surface and part of the lower surface of the lead frame 23, and having the light emitting elements 14 and the like embedded therein. On this occasion, the unevenness of the sheet 27 is transferred to the surface of the transparent resin plate 29a which has been in contact with the sheet 27.

Next, as shown in FIG. 18A, a combined body including the lead frame 23 and the transparent resin plate 29a is diced from the transparent resin plate 29a side by using a blade 104. Thus, portions of the lead frame 23 and the transparent resin plate 29a which are disposed in dicing regions D are removed. In this case, unevenness is provided on the cut surfaces in the transparent resin plate 29a by use of the unevenness on a surface of the blade 104. As a result of the cutting, portions of the lead frame 23 and the transparent resin plate 29a which are disposed in the element regions P are formed into individual pieces, and thus the first resin bodies 171, the first lead portions 11, and the second lead portions 12 as shown in FIG. 18B are manufactured.

Thereafter, the second resin bodies 172 are provided on the top surfaces and the side surfaces of the first resin bodies 171 as in the case of the method of manufacturing the light emitting device according to the first embodiment, which are shown in FIGS. 8A to 9C. Thus, the light emitting devices 51 each provided with the unevenness 173 in the interface between the first resin body 171 and the second resin body 172 are completed as shown in FIG. 18C.

Note that the method of manufacturing the light emitting device 51 described above is merely an example. For example, the first resin bodies 171 and the second resin bodies 172 may be formed using the molds illustrated in FIGS. 13A to 15B. In this case, unevenness is provided on the surface of the recess portion 101a of the mold 101 used to form the first resin bodies 171. Accordingly, the unevenness on the surface of the recess portion 101a of the mold 101 is transferred to the surfaces of the first resin bodies 171, and the unevenness 173 is provided in the interfaces between the first resin bodies 171 and the second resin bodies 172 to be formed later.

Moreover, in the light emitting device 51, the first resin body 171 may include a diffusing agent, instead of the unevenness 173, or together with the unevenness 173. Silica is used, for example, as the diffusing agent, and diffuses light emitted from the light emitting element 14. Thus, total reflection by the interface between the first resin body 171 and the second resin body 172 is reduced.

### Third Embodiment

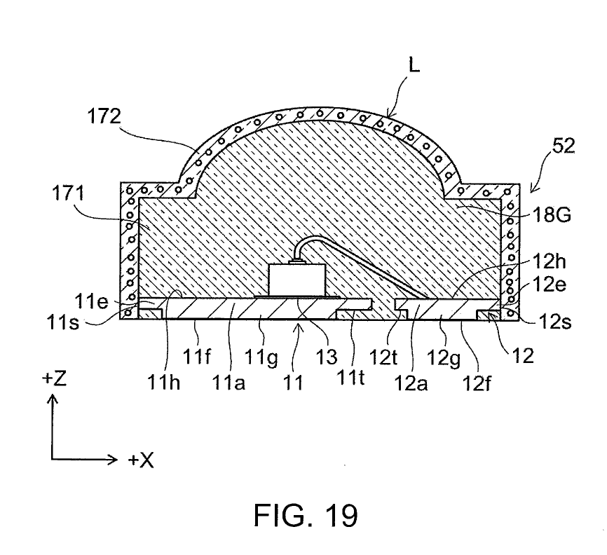

FIG. 19 is a schematic cross-sectional view illustrating a light emitting device according to a third embodiment.

As shown in FIG. 19, a light emitting device 52 according to this embodiment includes: a first lead portion 11 and a second lead portion 12 making a pair; a light emitting element 14 mounted on a base portion 11a on a first main surface s1 of the first lead portion 11 and the second lead portion 12; a first resin body 171 provided on the first main surface s1 side of the first lead portion 11 and the second lead portion 12 and covering the light emitting element 14; and a second resin body 172 covering a top surface 171a and side surfaces 171b of the first resin body 171, side surfaces 11s of the first lead portion 11, and side surfaces 12s of the second lead portion 12. Moreover, the light emitting device 52 is provided with a lens shape L by the first resin body 171 and the second resin body 172.

Such lens shape L is formed, for example, by using a manufacturing method using molds as illustrated in FIGS. 13A to 15B. In other words, molds corresponding to the lens shape L are provided respectively in the recess portions 101a, 110a of the molds 101, 110 which are used to form the first resin bodies 171 and the second resin bodies 172. Thus, the light emitting devices 52 each with the lens shape L formed by the first resin body 171 and the second resin body 172 are completed.

Since the lens shape L is formed by use of the molds 101, 110, the lens shape L of each light emitting device 52 may be a shape other than the convex shape illustrated in FIG. 19, such as a concave shape, an aspherical shape, or a cylindrical lens shape. Moreover, the number of lens shapes L is not limited to one, and multiple lens shapes L may be provided thereto.

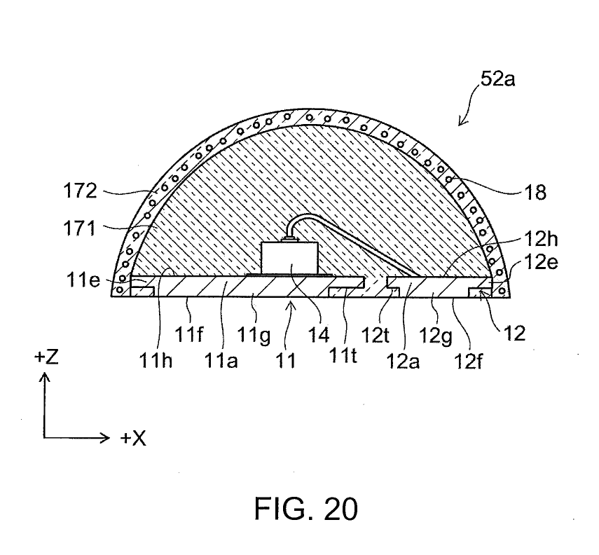

FIG. 20 is a schematic cross-sectional view illustrating a modification of the third embodiment.

The modification is a modification of the lens shape L.

As shown in FIG. 20, in a light emitting device 52a according to this modification, a first resin body 171 and a second resin body 172 as a whole are formed into a semi-spherical lens shape L. In the light emitting device 52a, the lens shape L of the first resin body 171 and second resin body 172 as a whole is formed by the shapes of the recess portions of the molds used to form the first resin bodies 171 and the second resin bodies 172.

The light emitting devices 52, 52a of the third embodiment make it possible to obtain optical characteristics of the lens shape L in addition to the operational effects of the light emitting device 1 of the first embodiment.

### Fourth Embodiment

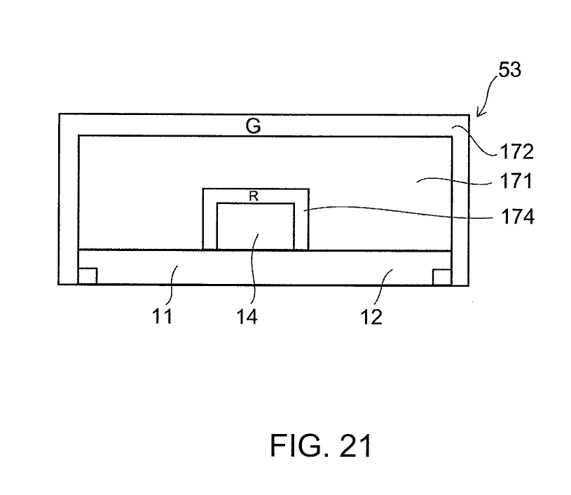

FIG. 21 is a schematic cross-sectional view illustrating a light emitting device of a fourth embodiment.

As shown in FIG. 21, in a light emitting device 53 according to the fourth embodiment, a third resin body 174 is provided on an upper surface and side surfaces of a light emitting element 14. In other words, the third resin body 174 is provided between the light emitting element 14 and a first resin body 171.

In this respect, the third resin body 174 includes phosphor (not illustrated). The thickness of the third resin body 174 is uniform. Accordingly, the difference in the distance that light travels through the third resin body 174 becomes smaller among various angles at which the light is radially emitted from the light emitting device 14.

In the light emitting device 53, for example, red phosphor R is mixed into the third resin body 174, and green phosphor G is mixed into the second resin body 172. In addition, the light emitting element 14 emits blue light. Thus, blue light emitted from the light emitting element 14 and not absorbed by the red phosphor R or the green phosphor G, red light emitted from the red phosphor R, and green light emitted from the green phosphor G are emitted from the light emitting device 53 For this reason, the light emitted therefrom is white as a whole.

### Fifth Embodiment

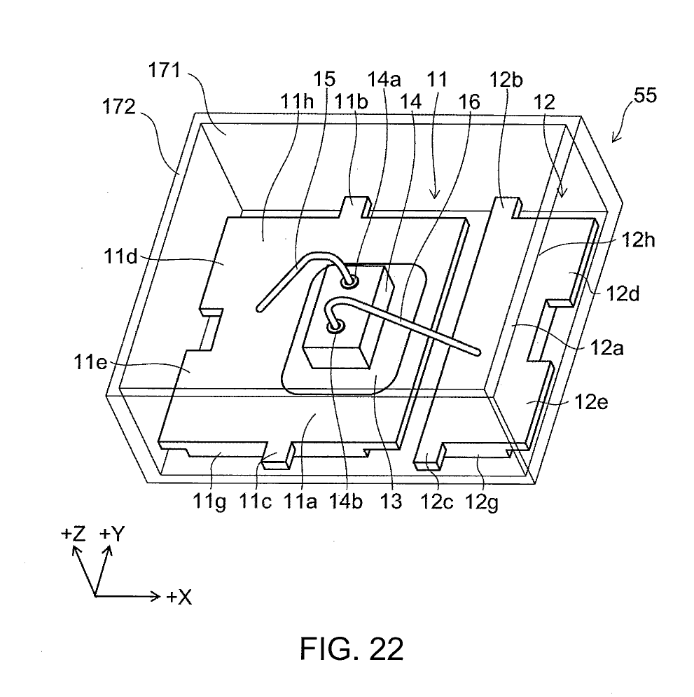

FIG. 22 is a perspective view illustrating a light emitting device according to a fifth embodiment.

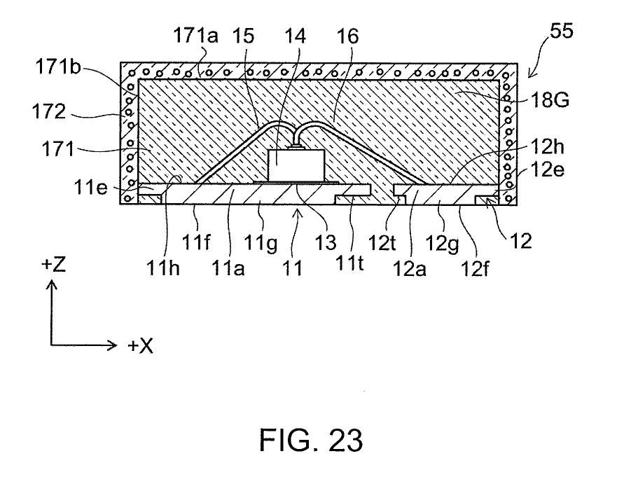

FIG. 23 is a cross-sectional view illustrating the light emitting device according to the fifth embodiment.

As shown in FIGS. 22 and 23, an upper-surface-terminal type light emitting element 14 is provided in a light emitting device 55 according to this embodiment. Specifically, terminals 14a, 14b are provided on an upper surface of the light emitting element 14. An end of a wire 15 is bonded to the terminal 14a of the light emitting element 14, and the other end of the wire 15 is bonded to an upper surface 11h of a first lead portion 11. Thus, the terminal 14a is connected to the first lead portion 11 via the wire 15. Meanwhile, an end of a wire 16 is bonded to the terminal 14b, and the other end of the wire 16 is bonded to an upper surface 12h of a second lead portion 12. Thus, the terminal 14b is connected to the second lead portion 12 via the wire 16. When such an upper-surface-terminal type light emitting element 14 is used, a die-mount material 13 may be an electrically conductive or insulating material. When the die-mount material 13 is an electrically insulating material, the die-mount material 13 is formed of, for example, transparent resin paste.

### Sixth Embodiment

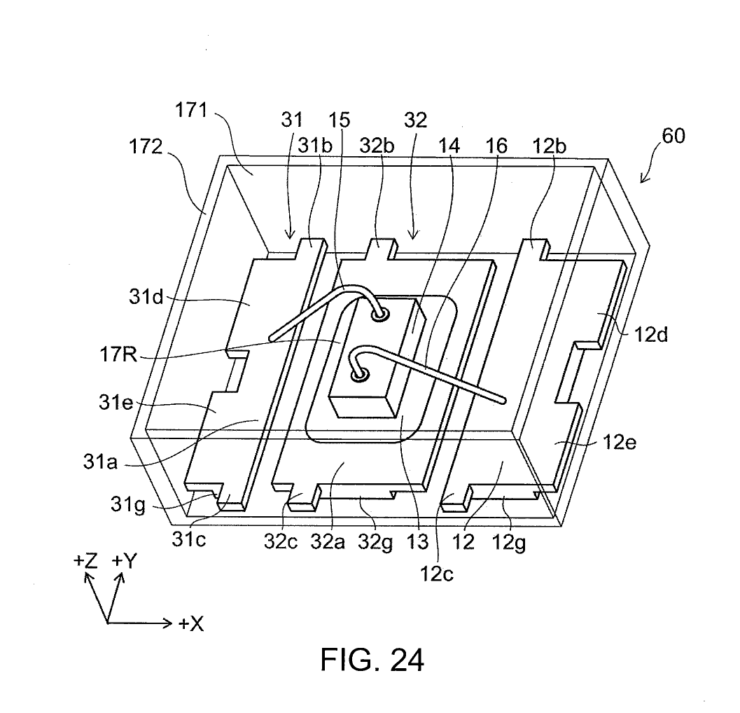

FIG. 24 is a perspective view illustrating a light emitting device of a 6th embodiment.

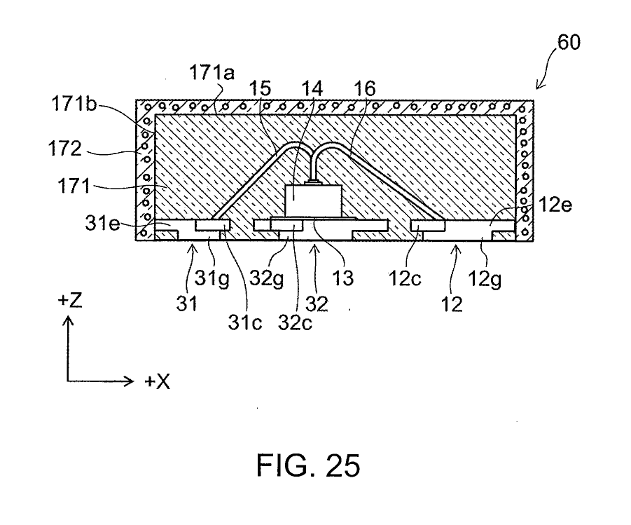

FIG. 25 is a cross-sectional view illustrating the light emitting device of the 6th embodiment.

As shown in FIGS. 24 and 25, a light emitting device 60 according to this embodiment is different from the light emitting device 1 (see FIG. 1) according to the first embodiment described above in that the first lead portion 11 (see FIG. 1) is divided into two lead frames 31, 32 in the X direction. The lead frame 32 is disposed between the lead frame 31 and a second lead portion 12. In addition, hanging pins 31d, 31e corresponding to the hanging pins 11d, 11e (see FIG. 1) of the first lead portion 11 are formed in the lead frame 31. Moreover, hanging pins 31b, 31c extending from a base portion 31a respectively in the +Y direction and the −Y direction are formed in the lead frame 31. The positions of the hanging pins 31b, 31c are the same in the X direction. Furthermore, a wire 15 is bonded to the lead frame 31. Meanwhile, hanging pins 32b, 32c corresponding to the hanging pins 11b, 11c (see FIG. 1) of the first lead portion 11 are formed in the lead frame 32, and a light emitting element 14 is mounted on the lead frame 32 with a die-mount material 13 interposed in between. Moreover, protruding portions corresponding to the protruding portion 11g of the first lead portion 11 are formed respectively on the lead frames 31 and 32 as protruding portions 31g, 32g.

In this embodiment, electric potential is applied to the lead frame 31 and the second lead portion 12 from the outside, as well as thereby the lead frame 31 and the second lead portion 12 function as external electrodes. Meanwhile, there is no need to apply electric potential to the lead frame 32, and the lead frame 32 may be used as a lead frame dedicated to heat sinking. By this configuration, when multiple light emitting devices are mounted on a single module, the lead frames 32 may be connected to a common heat sink. Note that a ground potential may be applied to the lead frame 32, or the lead frame 32 may be in a floating state. Moreover, if solder balls are bonded to the lead frames 31, 32 and the second lead portion 12, what is termed as the Manhattan phenomenon can be inhibited when the light emitting device 60 is mounted on a motherboard. The Manhattan phenomenon is a phenomenon in which, when a device or the like is mounted on a substrate with multiple solder balls and the like interposed in between, the device stands up due to variation in timing at which the solder balls melt in a reflow furnace, and due to surface tension of the solder. This phenomenon causes mounting defects. In this embodiment, the layout of the lead frames is symmetrical with respect to the X direction, and the solder balls are arranged densely in the X direction. Thus, the Manhattan phenomenon is less likely to occur.

Moreover, in this embodiment, since the lead frame 31 is supported by the hanging pins 31b to 31e in three directions, the quality of bonding the wire 15 is excellent. Similarly, since the second lead portion 12 is supported by the hanging pins 12b to 12e in three directions, the quality of bonding the wire 16 is excellent.

The light emitting device 60 as described above can be manufactured in a method similar to that of the first embodiment described above by changing the basic pattern of each of the element regions P of the lead frame 23 in the step shown in FIG. 5A described above.

### Seventh Embodiment

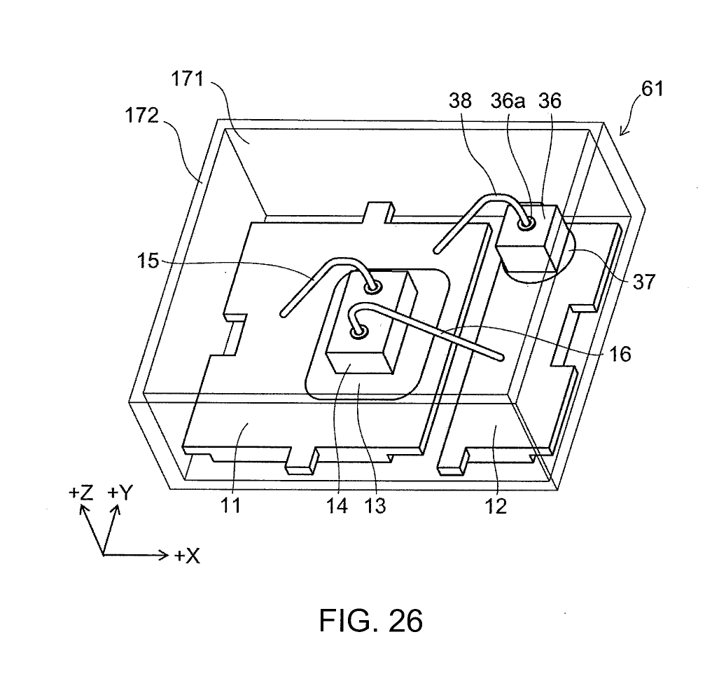

FIG. 26 is a perspective view illustrating a light emitting device of a seventh embodiment.

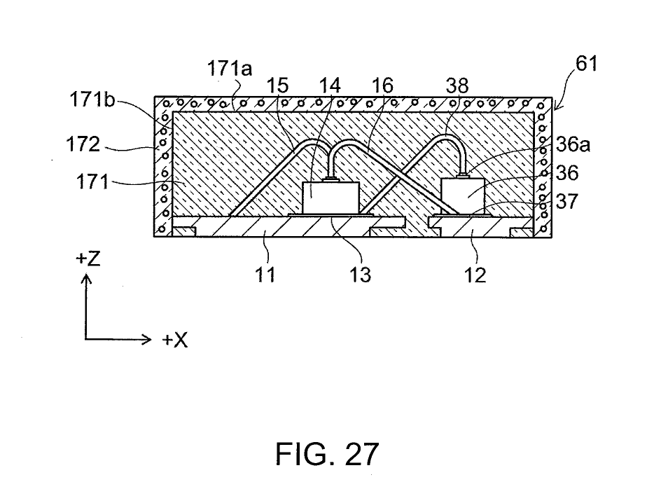

FIG. 27 is a cross-sectional view illustrating the light emitting device of the seventh embodiment.

As shown in FIGS. 26 and 27, a light emitting device 61 of the seventh embodiment is provided with a Zener diode chip 36 and the like in addition to the configuration of the light emitting device 1 (see FIG. 1) of the first embodiment which has been described previously. The Zener diode chip 36 and the like are connected between a first lead portion 11 and a second lead portion 12. In other words, a die-mount material 37 made of an electrically conductive material such as solder or silver paste is applied onto an upper surface of the second lead portion 12, and the Zener diode chip 36 is provided thereon. Thus, the Zener diode chip 36 is mounted on the second lead portion 12 with the die-mount material 37 interposed in between, and a lower surface terminal (not illustrated) of the Zener diode chip 36 is connected to the second lead portion 12 with the die-mount material 37 interposed in between. Moreover, an upper surface terminal 36a of the Zener diode chip 36 is connected to the first lead portion 11 via a wire 38. In other words, an end of the wire 38 is connected to the upper surface terminal 36a of the Zener diode chip 36. The wire 38 is lead out from the upper surface terminal 36a in the +Z direction, and curves in a direction between the −Z direction and the −X direction. The other end of the wire 38 is bonded to the upper surface of the first lead portion 11.

Hence, the Zener diode chip 36 can be connected in parallel to the light emitting element 14 in this embodiment. As a result, resistance against electrostatic discharge (ESD) is improved. The configuration, manufacturing method, and operational effects of this embodiment other than those described above are the same as those of the first embodiment described above.

### Eighth Embodiment

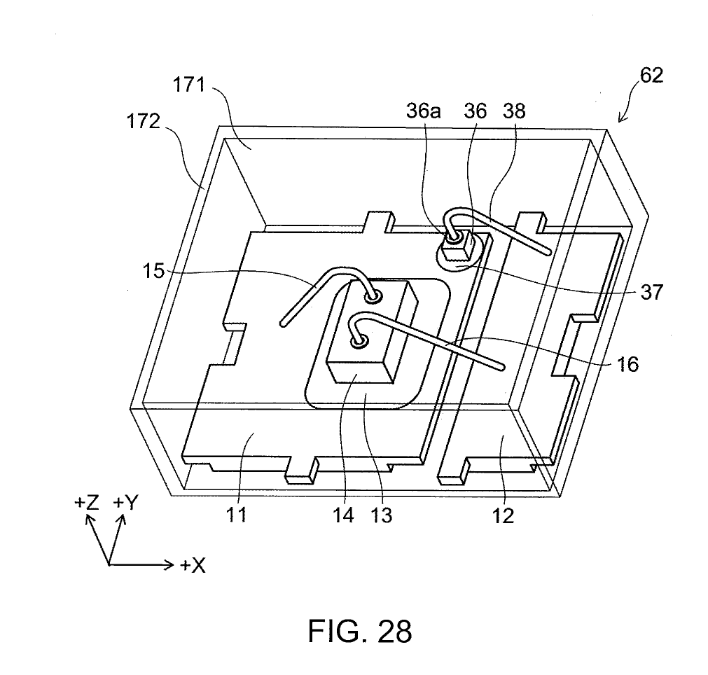

FIG. 28 is a perspective view illustrating a light emitting device of an eighth embodiment.

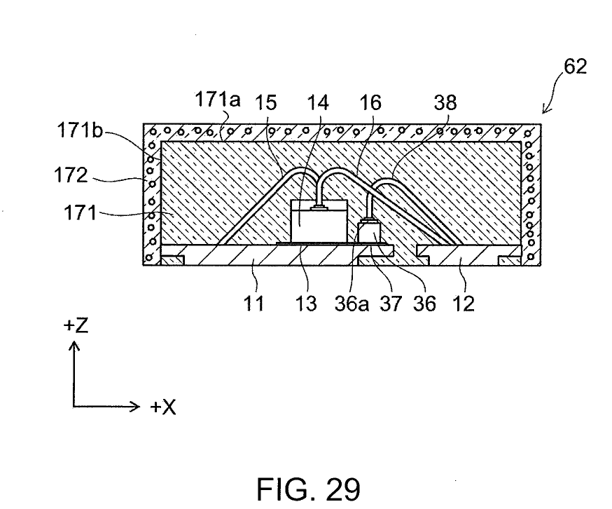

FIG. 29 is a cross-sectional view illustrating the light emitting device of the eighth embodiment.

As shown in FIGS. 28 and 29, a light emitting device 62 of this embodiment is different from the light emitting device 61 (see FIG. 26) of the seventh embodiment, which has been described previously, in that a Zener diode chip 36 is mounted on a first lead portion 11. In this case, a lower surface terminal of the Zener diode chip 36 is connected to the first lead portion 11 with a die-mount material 37 interposed in between, and an upper surface terminal thereof is connected to a second lead portion 12 via a wire 3eighthe configuration, manufacturing method, and operational effects of this embodiment other than those described above are the same as those of the first embodiment described above.

### Ninth Embodiment

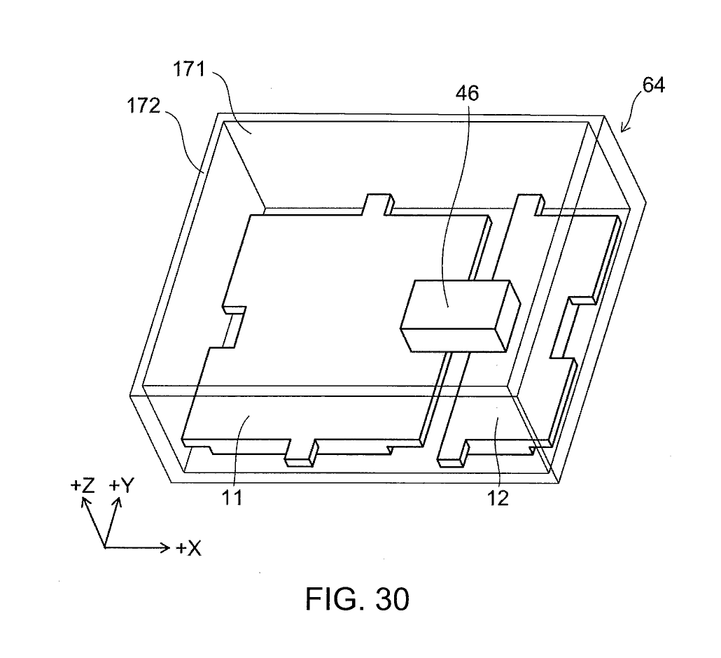

FIG. 30 is a perspective view illustrating a light emitting device of a 9th embodiment.

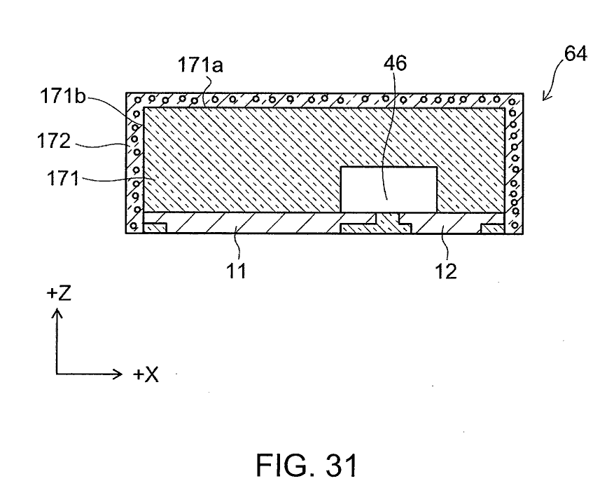

FIG. 31 is a cross-sectional view illustrating the light emitting device of the 9th embodiment.

As shown in FIGS. 30 and 31, a light emitting device 64 of this embodiment is different from the light emitting device 1 (see FIG. 1) of the first embodiment, which has been described previously, in that the light emitting device 64 is provided with a flip-type light emitting element 46 in lieu of the vertical conduction-type light emitting device 14. In other words, two terminals are provided on a lower surface of the light emitting element 46 in the light emitting device 64 of this embodiment. Moreover, the light emitting element 46 is disposed, like a bridge, stretching between a first lead portion 11 and a second lead portion 12. One of the lower surface terminals of the light emitting element 46 is connected to the first lead portion 11, and the other one of the lower surface terminals is connected to the second lead portion 12.

In this embodiment, the flip-type light emitting element 46 is used to eliminate a wire. This configuration improves the efficiency of outputting light upward, and enables the wire bonding step to be omitted. Moreover, breakage of a wire due to thermal stress of a first resin body 171 can be prevented. The configuration, manufacturing method, and operational effects of this embodiment other than those described above are the same as those of the first embodiment described above.

The embodiments and modifications thereof have been described above, but the present invention is not limited to these examples. For example, those skilled in the art may come up with a variation of any of the embodiments and modifications by adding or deleting the components or by changing the design of the components depending on the necessity, or may come up with a combination by combining the features of the embodiments depending on the necessity. Such variation and combination fall within the scope of the present invention as long as they include the gist of the present invention.

For example, in the embodiments and their modifications described above, given are examples in which: the light emitting element is an element which emits blue light; and the phosphor is a phosphor which absorbs blue light and emits yellow light, or phosphors which emit red light and green light. However, the present invention is not limited to this. The light emitting element may be an element which emits visible light other than the blue light, or may be an element which emits ultraviolet light or infrared light. Moreover, in the embodiments and their modifications described above, given are examples in which one or two resin bodies including phosphor are provided. However, three or more resin bodies including phosphor may be provided.

For example, a configuration may be adopted in which: the light emitting element is an element emitting ultraviolet light; and three second resin bodies respectively containing red phosphor, green phosphor, and blue phosphor is provided. Hence, all of the color components can be controlled by adjusting the types and the amounts of phosphors. Thus, latitude in color of the emitted light can be increased. In this case, a second resin body including a phosphor which emits light with shorter wavelength is disposed farther from the light emitting element. Alternatively, a second resin body including a phosphor with higher thermal dependency is disposed farther from the light emitting element. For example, the second resin body containing red phosphor, the second resin body containing green phosphor, and the second resin body containing blue phosphor are arranged in this order from the light emitting element.

As for the phosphor emitting blue light, the following substance may be given as an example:

(RE1-xSMx) 3 (AlyGa1-y) 5012:Ce

where 0≦x<1, 0≦y≦1, and RE is at least one selected from Y and Gd.

As for the phosphor emitting green light, the following substances may be given as an example in addition to the sialon-based green phosphor described above.

As for the phosphor emitting red light, the following substances may be given as an example in addition to the sialon-based red phosphor described above.

Note that as for the phosphor emitting yellow light, for example, the following phosphor may be used instead of the silicate-based phosphor described above. The phosphor is expressed with a general formula: MexSi12-(m+n)Al(m+n)OnN16-n:Re1yRe2z (where x, y, z, m, and n are coefficients). In this phosphor, part or all of the metal Me (one or two selected from a group consisting of Ca and Y) forming a solid solution with an alpha-sialon is substituted with a lanthanide metal Re1 (Re1 is one or more selected from a group consisting of Pr, Eu, Tb, Yb, and Er) which is the center of the light emission, or with two types of lanthanide metals Re1 and Re2 (Re2 is Dy), the lanthanide metal Re2 serving as a coactivator.

Moreover, the color of the light which the light emitting device as a whole emits is not limited to white. Any desired color tone may be achieved by adjusting the weight ratio R:G:B among the red phosphor, the green phosphor and the blue phosphor described above. For example, emission of white light ranging from incandescent-lamp-like white light to fluorescent-lamp-like white light can be achieved by setting the R:G:B weight ratio at any one of 1:1:1 to 7:1:1, 1:1:1 to 1:3:1, and 1:1:1 to 1:1:3.

In the first embodiment described above, an example is given in which the lead frame 23 is formed by wet etching. However, the present invention is not limited to this method, and the lead frame 23 may be formed by mechanical means such as a press.

In the first embodiment described above, an example is given in which the silver plating layers are formed on the upper and lower surfaces of the copper plate in the lead frame. However, the present invention is not limited to this. For example, the plating may be achieved by: forming the silver plating layers on the upper and lower surfaces of the copper plate; and forming a rhodium (Rh) plating layer on at least one of the silver plating layers. Alternatively, a copper (Cu) plating layer may be formed between the copper plate and each of the silver plating layers. Otherwise, the plating may be achieved by: forming nickel (Ni) plating layers on the upper and lower surfaces of the copper plate; and forming a plating layer of an alloy of gold and silver (Au—Ag alloy) or a palladium (Pd) plating layer on each of the nickel plating layers.

Moreover, a groove may be formed in a portion between a region where the die-mount material is to be applied on the upper surface of the lead frame and a region where the wire is to be bonded. Alternatively, a recess portion may be formed in the region where the die-mount material is to be applied on the upper surface of the lead frame. Accordingly, even when the amount of supplied die-amount material or the position into which to supply the die-mount material varies, the die-mount material is prevented from flowing out to the region where the wire is to be bonded, and it is thus possible to prevent the inhibition of the wire bonding.

In the embodiments and their modifications described above, examples are given in which one light emitting element is mounted on the light emitting device. However, multiple light emitting elements may be mounted on the light emitting device.

In the embodiments and their modifications described above, examples are given in which the lead made of the electrically conductive material is used as the base. However, the base is not limited to this configuration. For example, an electrically insulating substrate (such as a ceramic substrate) with a metal pattern formed thereon may be used. In a case of using the electrically insulating substrate, a single substrate with the metal pattern formed on a main surface thereof is used. For example, a first metal pattern on which to mount the light emitting element 14 and a second metal pattern to which to connect the wire 16 are provided spaced out on the main surface of the substrate. In this respect, the first metal pattern and the second metal pattern are used, respectively, as the first lead portion 11 and the second lead portion 12 in common with the above embodiments.

In the embodiments and their modifications described above, examples are given in which the recess portions DP provided on the side surfaces of the lead (base) are formed to extend from the first main surface s1 to the second main surface s2. However, the recess portions DP may be provided to extend from the first main surface s1 with a depth not reaching the second main surface s2. In other words, the recess portions DP may be shaped like a groove formed from the first main surface s1. In this case, the second resin body 172 is provided in a way that its coverage extends from the first main surface to at least a position of the lowermost end of the recess portions DP in the direction orthogonal to the first main surface s1 (a position farthest from the first main surface s1).

As described above, the light emitting devices of the embodiments brings about the following operational effects. The difference in the distance for the light travels through the second resin body 172 containing the phosphor 18 becomes smaller among angles at which the light is emitted radially from the light emitting element 14. Thus, variation in the wavelength conversion by the phosphor 18 can be suppressed among the angles at which the light is emitted radially. Accordingly, dependency of the chromaticity of the emitted light on its angle can be suppressed in the light emitting device 1.

Moreover, since the side surfaces 171b of the first resin body 171, the side surfaces 11s of the first lead portion 11, and the side surfaces 12s of the second lead portion 12 are covered with the second resin body 172, light leaking from the space between the first lead portion 11 and the second lead portion 12 also travels through the second resin body 172. Thus, the light leaking from the space between the first lead portion 11 and the second lead portion 12 are also subjected to the wavelength conversion by the phosphor 18.

Moreover, since the side surfaces 11s of the first lead portion 11 and the side surfaces 12s of the second lead portion 12, that is to say, the leading end surfaces of the hanging pins 11b to 11e, 12b to 12e are covered with the second resin body 172, corrosion of the first lead portion 11 and the second lead portion 12 is prevented from occurring from these surfaces.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A light emitting device, comprising:
a base provided with a recess portion in a side surface thereof;
a light emitting element mounted on a main surface of the base;
a first resin body filled in an inside of the recess portion, and covering at least the main surface and the light emitting element;
a second resin body covering an outside of the first resin body from the main surface side to at least a position of the lowermost end of the recess portion in a direction orthogonal to the main surface; and
phosphor, provided in the second resin body, for absorbing light emitted from the light emitting element and then emitting light having a different wavelength.

2. The light emitting device according to claim 1, wherein the base includes a first base portion and a second base portion provided away from each other, and the first resin body is filled in a space between the first base portion and the second base portion as well.

3. The light emitting device according to claim 1, wherein the first resin body is made of a translucent resin which transmits the light emitted from the light emitting element.

4. The light emitting device according to claim 1, wherein a thickness of the second resin body is uniform.

5. A method of manufacturing a light emitting device comprising the steps of:
mounting a light emitting element on a main surface of a base provided with a recess portion in a side surface thereof;
filling an inside of the recess portion with a first resin, and covering at least the main surface and the light emitting element with the first resin;
forming a first resin body by cutting the first resin at a position around the light emitting element;
covering an outside of the first resin body with a second resin from the main surface side to a position of the lowermost end of the recess portion in a direction orthogonal to the main surface, the second resin containing phosphor; and
forming a second resin body by dividing the second resin at a position around the first resin body.
